(19) United States
(12) Patent Application Publication
(10) Pub. No.: US 2023/0238495 A1
(43) Pub. Date: Jul. 27, 2023

(54) DISPLAY DEVICE AND MANUFACTURING METHOD OF MANUFACTURING THE SAME

(71) Applicant: SAMSUNG DISPLAY CO., LTD., Yongin-si (KR)

(72) Inventors: Nak Cho CHOI, Yongin-si (KR); Sang Woo AN, Asan-si (KR)

(21) Appl. No.: 18/048,135

(22) Filed: Oct. 20, 2022

(30) Foreign Application Priority Data
Jan. 24, 2022 (KR) 10-2022-0010059
Mar. 22, 2022 (KR) 10-2022-0035195

(51) Int. Cl. H01L 33/62; H01L 33/00; H01L 25/075; G09F 9/302

(52) U.S. Cl. CPC H01L 33/62; H01L 33/005; H01L 25/0753; G09F 9/3026; H01L 2933/0066

(57) ABSTRACT

A display device is provided, a display device includes, a substrate including a first surface, a second surface opposite to the first surface, a first chamfered surface extending from one side of the first surface, a second chamfered surface extending from one side of the second surface, and a first side surface connecting the first chamfered surface and the second chamfered surface to each other, a first pad on the first surface, an upper via layer on the first surface and spaced from the first pad, and a first passivation layer partially covering the upper via layer, and defining a first exposure opening exposing one side of the upper via layer facing the first pad.

### CROSS-REFERENCE TO RELATED APPLICATION

This application claims priority to, and the benefit of, Korean Patent Application No. 10-2022-0010059 filed on Jan. 24, 2022 in the Korean Intellectual Property Office, and Korean Patent Application No. 10-2022-0035195 filed on Mar. 22, 2022 in the Korean Intellectual Property Office, the contents of both of which, in their entirety, being herein incorporated by reference.

### BACKGROUND

### 1. Field

The disclosure relates to a display device and a manufacturing method of the same.

### 2. Description of the Related Art

Electronic devices, such as smartphones, tablet personal computers (PCs), digital cameras, laptop computers, navigation systems, and smart televisions that provide images to users include display devices for displaying the images.

The display device includes a display area capable of expressing various colors while operating in units of pixels or sub-pixels, and a bezel area in which lines for driving the pixels or the sub-pixels are located.

Recently, the demand for a bezel-less technology of decreasing or eliminating the bezel area so as to increase or maximize the display area in the display device has increased, and accordingly, research and development of a side wiring forming technology of forming lines on side surfaces of a substrate have been steadily conducted.

### SUMMARY

Aspects of the disclosure provide a display device having improved reliability.

Aspects of the disclosure also provide a manufacturing method of a display device having improved reliability.

However, aspects of the disclosure are not restricted to those set forth herein. The above and other aspects of the disclosure will become more apparent to one of ordinary skill in the art to which the disclosure pertains by referencing the detailed description of the disclosure given below.

According to one or more embodiments of the disclosure, a display device includes a substrate including a first surface, a second surface opposite to the first surface, a first chamfered surface extending from one side of the first surface, a second chamfered surface extending from one side of the second surface, and a first side surface connecting the first chamfered surface and the second chamfered surface to each other, a first pad on the first surface, an upper via layer on the first surface and spaced from the first pad, and a first passivation layer partially covering the upper via layer, and defining a first exposure opening exposing one side of the upper via layer facing the first pad.

The display device may further include a second pad on the second surface, and a side wiring on the first surface, on the first chamfered surface, on the first side surface, and on the second chamfered surface, and electrically connecting the first pad and the second pad to each other.

The display device may further include an interlayer insulating layer between the first pad and the substrate, and between the upper via layer and the substrate, wherein the side wiring is in direct contact with the interlayer insulating layer in an area between the first pad and the upper via layer.

The side wiring may be spaced from the one side of the upper via layer facing the first pad.

The display device may further include an overcoat layer covering the side wiring, and in direct contact with the one side of the upper via layer facing the first pad.

The display device may further include a lower via layer on the second pad, and a second passivation layer partially covering the lower via layer, wherein the second pad is closer to the second chamfered surface than the lower via layer, and wherein the second passivation layer defines a second exposure opening exposing one side of the lower via layer adjacent to the second chamfered surface.

The side wiring may be spaced from the one side of the lower via layer adjacent to the second chamfered surface.

The overcoat layer may be in direct contact with the one side of the lower via layer adjacent to the second chamfered surface.

The upper via layer may include a first via layer on the substrate, a second via layer on the first via layer, and a third via layer on the second via layer, wherein the display device further includes a thin film transistor between the first via layer and the substrate, and a light emitting element on the third via layer, and electrically connected to the thin film transistor.

The one side of the upper via layer facing the first pad and exposed by the first exposure opening may include at least one of one side of the first via layer facing the first pad, one side of the second via layer facing the first pad, or one side of the third via layer facing the first pad.

The display device may further include light emitting elements, which include the light emitting element, that are spaced from each other, wherein the upper via layer further includes fourth via layers between the light emitting elements, on the third via layer, and including an outermost fourth via layer adjacent to the first pad, and wherein the first passivation layer defines a second exposure opening exposing one side of the outermost fourth via layer adjacent to the first pad.

The light emitting element may be a flip chip-type micro light emitting diode element.

According to one or more other embodiments of the disclosure, a display device includes a substrate including a display area in which pixels are located, a pad area at one side of the display area, and an inclined area on one side of the pad area, a passivation layer covering the display area and the pad area of the substrate, a via layer between the substrate and the passivation layer in the display area, and a pad between the substrate and the passivation layer in the pad area, wherein the passivation layer defines a first exposure opening adjacent a boundary between the display area and the pad area in the display area, and exposing the via layer, and a second exposure opening in the pad area and exposing the pad.

The display device may further include a side wiring in the pad area and in the inclined area, and electrically connected to the pad through the second exposure opening.

The side wiring may be spaced from the first exposure opening.

The display device may further include side wirings, which include the side wiring, that are spaced from each other in a first direction, wherein the first exposure opening extends in the first direction to correspond to the side wirings.

The pixels may include an outermost pixel adjacent to the pad area, wherein the passivation layer further defines a third exposure opening adjacent to the outermost pixel, and spaced from the first exposure opening with the outermost pixel interposed therebetween.

The display device may further include side wirings, which include the side wiring, that are spaced from each other in a first direction, wherein the passivation layer further defines first exposure openings, which include the first exposure opening, that are spaced from each other in the first direction.

According to one or more embodiments of the disclosure, a manufacturing method of a display device includes preparing a substrate including a first surface on which a first pad, a via layer spaced from the first pad, and an insulating layer covering the via layer are located, a second surface on which a second pad is located and that opposes the first surface, a first chamfered surface extending from one side of the first surface, a second chamfered surface extending from one side of the second surface, and a first side surface connecting the first chamfered surface and the second chamfered surface to each other, forming an exposure opening in the insulating layer to expose one side of the via layer facing the first pad, forming a side wiring material layer on the first surface, the second surface, the first chamfered surface, the second chamfered surface, and the first side surface of the substrate, and electrically connecting the first pad and the second pad to each other, and forming a side wiring by irradiating the side wiring material layer with a laser, wherein the first pad is closer to the first chamfered surface than the via layer.

The forming of the side wiring may include discharging an exhaust gas generated by irradiating the via layer with the laser.

The exhaust gas may be discharged through the exposure opening.

According to one or more embodiments of the disclosure, a tiled display device includes display devices, and seam parts between the display devices, wherein a first display device of the display devices includes a substrate including a first surface, a second surface opposite to the first surface, a first chamfered surface extending from one side of the first surface, a second chamfered surface extending from one side of the second surface, and a first side surface connecting the first chamfered surface and the second chamfered surface to each other, an upper via layer on the first surface, a first pad on the first surface and spaced from the upper via layer, light emitting elements on the upper via layer, and an first passivation layer covering the upper via layer, and defining a first exposure opening exposing one side of the upper via layer facing the first pad.

The light emitting elements may include a flip chip-type micro light emitting diode element.

The substrate may include glass.

The first display device may further include a side wiring on the first surface, on the second surface, and on the first side surface of the substrate, and connected to the first pad.

The first display device may further include a lower surface connection line on the second surface, and connected to the side wiring, and a flexible film connected to the lower surface connection line through a conductive adhesive member.

The display devices may be arranged in a matrix form.

With a display device according to embodiments, reliability of the display device may be improved. Further, with a manufacturing method of a display device according to embodiments, a display device having improved reliability may be provided.

The aspects of the disclosure are not limited to the aforementioned aspects, and various other aspects are included in the present specification.

### BRIEF DESCRIPTION OF THE DRAWINGS

The above and other aspects of the disclosure will become more apparent by describing in detail embodiments thereof with reference to the attached drawings, in which:

FIG. 1 is a perspective view illustrating a front surface of a display device according to one or more embodiments;

FIG. 2 is a perspective view illustrating a rear surface of the display device according to one or more embodiments;

FIG. 3 is a schematic view illustrating a structure of a pixel of the display device according to one or more embodiments;

FIG. 4 is a schematic view illustrating a structure of a pixel of a display device according to one or more other embodiments;

FIG. 5 is a schematic cross-sectional view illustrating a cross-sectional structure of a pixel according to one or more embodiments;

FIG. 6 is a perspective view illustrating an arrangement relationship between pixels and side wirings of the display device according to one or more embodiments;

FIG. 7 is a plan view illustrating the arrangement relationship between the pixels and the side wirings of the display device according to one or more embodiments;

FIG. 8 is a rear view illustrating an arrangement relationship between the side wirings and a driver of the display device according to one or more embodiments;

FIG. 9 is a cross-sectional view illustrating a cross section taken along the line X1-X1′ of FIG. 8;

FIG. 10 is a plan view illustrating a profile of an upper passivation layer covering a top surface of a substrate of FIG. 9;

FIGS. 11 to 16 are a flow chart and views for describing a manufacturing method of the display device according to one or more embodiments;

FIG. 17 is a schematic view illustrating a tiled display using the display device according to one or more embodiments;

FIG. 18 is an enlarged view of area A of FIG. 17;

FIG. 19 is a cross-sectional view illustrating a cross-section taken along the line X2-X2′ of FIG. 18;

FIG. 20 is a block diagram illustrating a structure of the tiled display according to one or more embodiments;

FIG. 21 is a view illustrating a state in which the tiled display using the display device according to one or more embodiments is driven;

FIG. 22 is a schematic cross-sectional view illustrating a structure of a display device according to one or more other embodiments;

FIG. 23 is a plan view illustrating a profile of an upper passivation layer covering a front surface of a substrate of a display device according to still one or more other embodiments;

FIG. 24 is a view illustrating a via layer exposed by an exposure opening according to still one or more other embodiments of FIG. 23;

FIG. 25 is a view illustrating a via layer covered by a shielding pattern according to still one or more other embodiments of FIG. 23; and

FIG. 26 is a schematic cross-sectional view illustrating a structure of a display device according to still one or more other embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components, such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions, such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression, such as “at least one of A and B” may include A, B, or A and B. As used herein, “or” generally means “and/or,” and the term “and/or” includes any and all combinations of one or more of the associated listed items. For example, the expression, such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Some embodiments are described in the accompanying drawings in relation to functional block, unit, and/or module. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

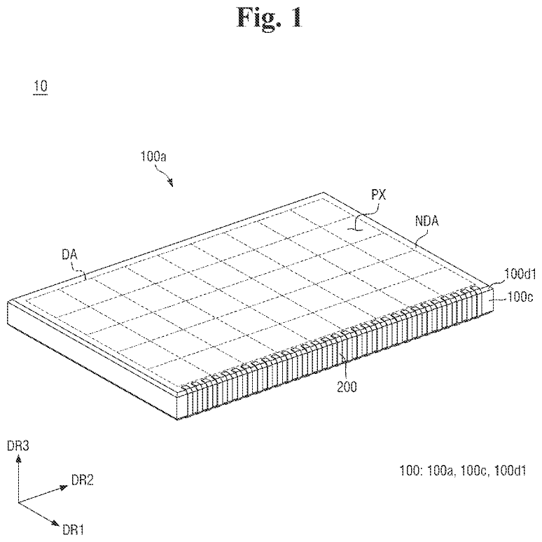

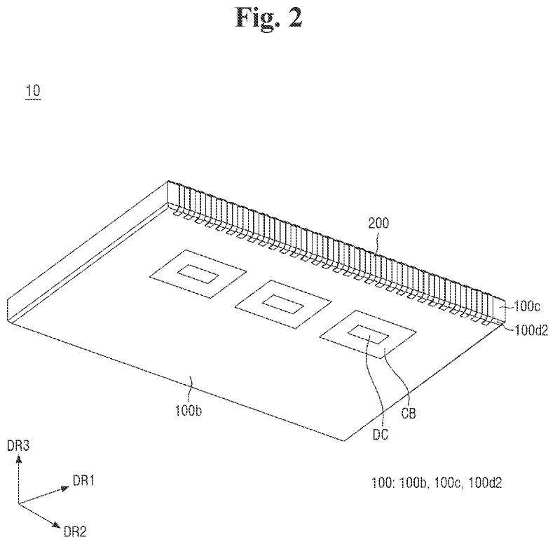

FIG. 1 is a perspective view illustrating a front surface of a display device according to one or more embodiments. FIG. 2 is a perspective view illustrating a rear surface of the display device according to one or more embodiments.

In FIG. 1, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 refers to a longitudinal direction in the drawing, the second direction DR2 refers to a transverse direction in the drawing, and the third direction DR3 refers to upward and downward directions, that is, a thickness direction, in the drawing. In the following specification, unless otherwise specified, the term “direction” may refer to both directions toward both sides extending along the direction. In addition, when both “directions” extending to both sides need to be distinguished from each other, one side will be referred to as “one side in the direction” and the other side will be referred to as “the other side in the direction”. In FIG. 1, an arrow direction will be referred to as one side, and an opposite direction to the arrow direction will be referred to as the other side.

Hereinafter, for convenience of explanation, in referring to a display device 10 or surfaces of respective members constituting the display device 10, one surface facing one side in a direction in which an image is displayed, that is, the third direction DR3 will be referred to as an upper surface, and the other surface opposite to the one surface will be referred to as a lower surface. However, the disclosure is not limited thereto, and the one surface and the other surface of the member may be referred to as a front surface and a rear surface, respectively, or may be referred to as a first surface or a second surface, respectively. In addition, in describing relative positions of the respective members of the display device 10, one side in the third direction DR3 may be referred to as an upper portion and the other side in the third direction DR3 may be referred to as a lower portion.

Referring to FIGS. 1 and 2, a display device 10 according to one or more embodiments may be applied to portable electronic devices, such as mobile phones, smartphones, tablet personal computers (PCs), mobile communication terminals, electronic notebooks, electronic books, portable multimedia players (PMPs), navigation devices, and ultra-mobile PCs (UMPCs). Alternatively, the display device 10 according to one or more embodiments may be applied as a display for televisions, laptop computers, monitors, billboards, or the Internet of Things (IOTs).

The display device 10 may have a shape similar to a rectangular shape in plan view. For example, the display device 10 may have short sides in the first direction DR1 and long sides in the second direction DR2, as illustrated in FIG. 1. A corner where the short side in the first direction DR1 and the long side in the second direction DR2 meet may be rounded with a curvature (e.g., predetermined curvature) or may be substantially right-angled. The shape of the display device 10 in plan view is not limited to the rectangular shape, and may also be a shape similar to other polygonal shapes, a circular shape, or an elliptical shape.

The display device 10 may include a display area DA in which a screen is displayed, and a non-display area NDA that is an area other than the display area DA and in which a screen is not displayed, on one side surface (hereinafter referred to as an upper surface) thereof in the third direction DR3. For example, the non-display area NDA may be located on a portion of the upper surface of the display device 10, on both side surfaces (hereinafter, referred to as side surfaces) of the display device 10 in the second direction DR2, on both side surfaces of the display device 10 in the first direction DR1, and on the other side surface (hereinafter referred to as a lower surface) of the display device 10 in the third direction DR3, but is not limited thereto. In some embodiments, the non-display area NDA may be located to surround edges of the display area DA, but is not limited thereto. Meanwhile, the display area DA and the non-display area NDA of the display device 10 may also be applied to a substrate 100 to be described later.

The display device 10 according to one or more embodiments may include a substrate 100, a plurality of pixels PX, a plurality of side wirings 200, and a driver, which may include circuit boards CB and display driver circuits DC.

The substrate 100 may serve as a base of the display device 10. In some embodiments, the substrate 100 may be a rigid substrate having rigidity and including glass, but is not limited thereto. For example, the substrate 100 may also be a flexible substrate having flexibility and including polyimide. Hereinafter, for convenience of explanation, it will be mainly described that the substrate 100 is the rigid substrate and includes the glass.

The substrate 100 may have a three-dimensional shape similar to a rectangular parallelepiped, and may have a shape in which edges formed by an upper surface and side surfaces constituting the rectangular parallelepiped and edges formed by a lower surface and the side surfaces forming the rectangular parallelepiped are bent. In other words, the substrate 100 may have a three-dimensional shape similar to a rectangular parallelepiped, and may have a shape in which edges of an upper surface and a lower surface thereof are bent. It has been illustrated in FIGS. 1 and 2 that chamfered surfaces are formed on both sides of the upper and lower surfaces of the substrate 100 in the first direction DR1 and both sides of the upper and lower surfaces of the substrate 100 in the second direction DR2. In some embodiments, surfaces of which edges are bent, that is, chamfered surfaces may be formed on both sides of the upper and lower surfaces of the substrate 100 in the first direction DR1 and both sides of the upper and lower surfaces of the substrate 100 in the second direction DR2, but are not limited thereto. For example, the chamfered surfaces may be formed only on one side of each of the upper and lower surfaces of the substrate 100 in the first direction DR1. Hereinafter, for convenience of explanation, it will be mainly described that chamfered surfaces are formed on both sides of the upper and lower surfaces of the substrate 100 in the first direction DR1 and both sides of the upper and lower surfaces of the substrate 100 in the second direction DR2.

The substrate 100 may include a first surface 100a, a second surface 100b, a plurality of chamfered surfaces, and a plurality of side surfaces.

The first surface 100a may be an upper surface of the substrate 100. The first surface 100a may have a rectangular shape having short sides in the first direction DR1 and long sides in the second direction DR2.

The second surface 100b may be a surface opposing, or opposite to, the first surface 100a in the third direction DR3. The second surface 100b may be a lower surface of the substrate 100. The second surface 100b may have a rectangular shape having short sides in the first direction DR1 and long sides in the second direction DR2.

The plurality of side surfaces are surfaces located between the first surface 100a and the second surface 100b, and may be both side surfaces of the substrate 100 in the first direction DR1 and both side surfaces of the substrate 100 in the second direction DR2. For convenience of explanation, a side surface located on one side in the first direction DR1 among the plurality of side surfaces will be referred to as a first side surface 100c, a side surface located on one side in the second direction DR2 among the plurality of side surfaces will be referred to as a second side surface, a side surface located on the other side in the first direction DR1 among the plurality of side surfaces will be referred to as a third side surface, and a side surface located on the other side in the second direction DR2 among the plurality of side surfaces will be referred to as a fourth side surface.

The plurality of chamfered surfaces refer to surfaces located between the first surface 100a and the plurality of side surfaces, and between the second surface 100b and the plurality of side surfaces. The chamfered surfaces are chamfered obliquely to reduce or prevent chipping defects from occurring in the plurality of side wirings 200. Due to the plurality of chamfered surfaces, a bent angle of each of the plurality of side wirings 200 may be gentle (e.g., relatively oblique), and thus, the occurrence of chipping or cracks in the plurality of side wirings 200 may be reduced or prevented. For convenience of explanation, a chamfered surface located between the first surface 100a and the first side surface 100c among the plurality of chamfered surfaces will be referred to as a first chamfered surface 100d1, a chamfered surface located between the second surface 100b and the first side surface 100c among the plurality of chamfered surfaces will be referred to as a second chamfered surface 100d2, a chamfered surface located between the first surface 100a and the second side surface among the plurality of chamfered surfaces will be referred to as a third chamfered surface, a chamfered surface located between the second surface 100b and the second side surface among the plurality of chamfered surfaces will be referred to as a fourth chamfered surface, a chamfered surface located between the first surface 100a and the third side surface among the plurality of chamfered surfaces will be referred to as a fifth chamfered surface, a chamfered surface located between the second surface 100b and the third side surface among the plurality of chamfered surfaces will be referred to as a sixth chamfered surface, a chamfered surface located between the first surface 100a and the fourth side surface among the plurality of chamfered surfaces will be referred to as a seventh chamfered surface, and a chamfered surface located between the second surface 100b and the fourth side surface among the plurality of chamfered surfaces will be referred to as an eighth chamfered surface.

For example, the first chamfered surface 100d1 may extend from one side of the first surface 100a in the first direction DR1, the second chamfered surface 100d2 may extend from one side of the second surface 100b in the first direction DR1, and the first side surface 100c may connect the first chamfered surface 100d1 and the second chamfered surface 100d2 to each other. The third chamfered surface may extend from one side of the first surface 100a in the second direction DR2, the fourth chamfered surface may extend from one side of the second surface 100b in the second direction DR2, and the second side surface may connect the third chamfered surface and the fourth chamfered surface to each other. The fifth chamfered surface may extend from the other side of the first surface 100a in the first direction DR1, the sixth chamfered surface may extend from the other side of the second surface 100b in the first direction DR1, and the third side surface may connect the fifth chamfered surface and the sixth chamfered surface to each other. The seventh chamfered surface may extend from the other side of the first surface 100a in the second direction DR2, the eighth chamfered surface may extend from the other side of the second surface 100b in the second direction DR2, and the fourth side surface may connect the seventh chamfered surface and the eighth chamfered surface to each other.

The plurality of pixels PX may be located on the first surface 100a of the substrate 100 to display an image. The plurality of pixels PX may be arranged in a matrix form in the first direction DR1 and the second direction DR2. A structure of the plurality of pixels PX will be described in detail later.

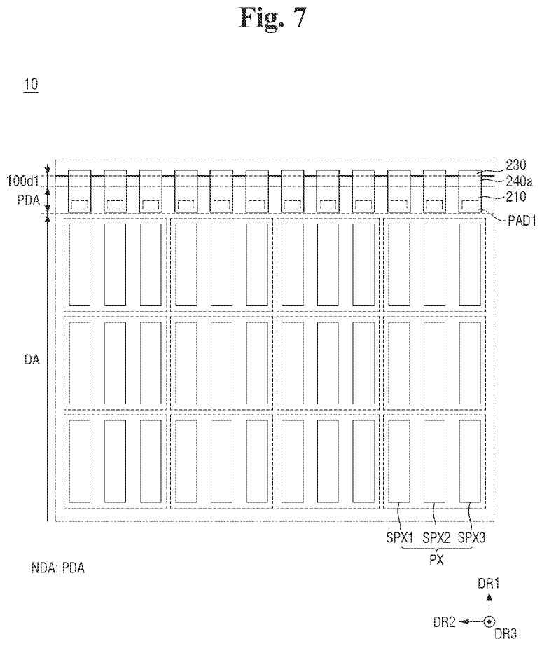

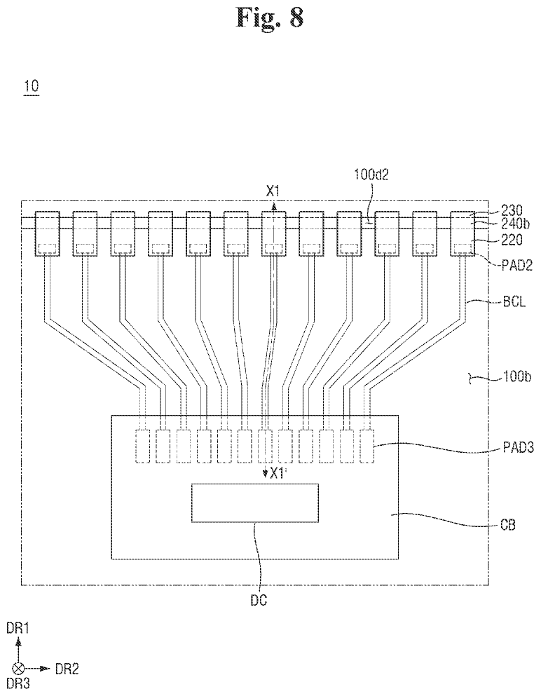

The plurality of side wirings 200 serve to connect first pads PAD1 (see FIG. 7) located on the first surface 100a and second pads PAD2 (see FIG. 8) located on the second surface 100b to each other, respectively. The first pads PAD1 may be connected to data lines connected to the plurality of pixels PX located on the first surface 100a of the substrate 100. The plurality of side wirings 200 may be arranged to be spaced apart from each other in the second direction DR2.

The plurality of side wirings 200 may be located on the first surface 100a, the second surface 100b, at least two of the plurality of chamfered surfaces, and at least one of the plurality of side surfaces. For example, the plurality of side wirings 200 may be located on the first surface 100a, the second surface 100b, the first chamfered surface 100d1, the second chamfered surface 100d2, and the first side surface 100c to connect the first pads PAD1 located on one side of the first surface 100a of the substrate 100 in the first direction DR1 and the second pads PAD2 located on one side of the second surface 100b of the substrate 100 in the first direction DR1 to each other, as illustrated in FIGS. 1 and 2. A shape of each of the plurality of side wirings 200 will be described in detail later.

In some embodiments, the plurality of side wirings 200 may be located only on one side of the substrate 100 in the first direction DR1, but are not limited thereto. For example, the plurality of side wirings 200 may also be located on the other side of the substrate 100 in the first direction DR1, on one side of the substrate 100 in the second direction DR2, or on the other side of the substrate 100 in the second direction DR2. In this case, the first pads PAD1 located on the first surface 100a of the substrate 100 may be additionally located on the other side of the first surface 100a of the substrate 100 in the first direction DR1, on one side of the first surface 100a of the substrate 100 in the second direction DR2, or on the other side of the first surface 100a of the substrate 100 in the second direction DR2, and the second pads PAD2 located on the second surface 100b of the substrate 100 may be additionally located on the other side of the second surface 100b of the substrate 100 in the first direction DR1, on one side of the second surface 100b of the substrate 100 in the second direction DR2, or on the other side of the second surface 100b of the substrate 100 in the second direction DR2. Hereinafter, for convenience of explanation, it will be mainly described that the plurality of side wirings 200 are located only on one side of the substrate 100 in the first direction DR1.

The circuit boards CB may be located on the second surface 100b of the substrate 100. Each of the circuit boards CB may be connected to third pads PAD3 (see FIG. 8) located on the second surface 100b of the substrate 100 using a conductive adhesive member, such as an anisotropic conductive film. As described later, the third pads PAD3 are electrically connected to the second pads PAD2, respectively, and thus, the circuit board CB may be electrically connected to the first pads PAD1 through the side wirings 200. Each of the circuit boards CB may be a flexible printed circuit board, a printed circuit board, or a flexible film, such as a chip on film.

The display driving circuit DC may generate data voltages and may supply the data voltages to the data lines extending from the pixels PX through the circuit board CB, the third pads PAD3, the second pads PAD2, the plurality of side wirings 200, and the first pads PAD1. The display driving circuit DC may be formed as an integrated circuit (IC) and may be attached onto the circuit board CB. Alternatively, the display driving circuit DC may be directly attached to the second surface 100b of the substrate 100 in a chip-on-glass (COG) manner.

By connecting the first pads PAD1 located on the first surface 100a with the second pads PAD2 located on the second surface 100b using the plurality of side wirings 200 as described above, a flexible film bent along a side surface of the substrate 100 may be omitted, and thus, a bezel-less display device 10 in which the non-display area NDA is reduced or minimized may be implemented.

Hereinafter, a structure of the pixel PX of the display device 10 according to one or more embodiments will be described.

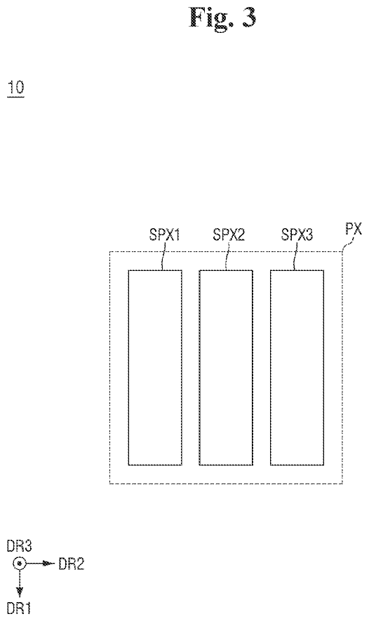

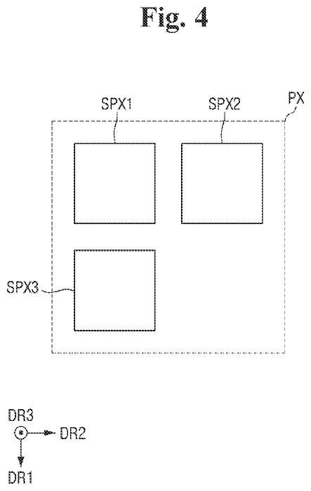

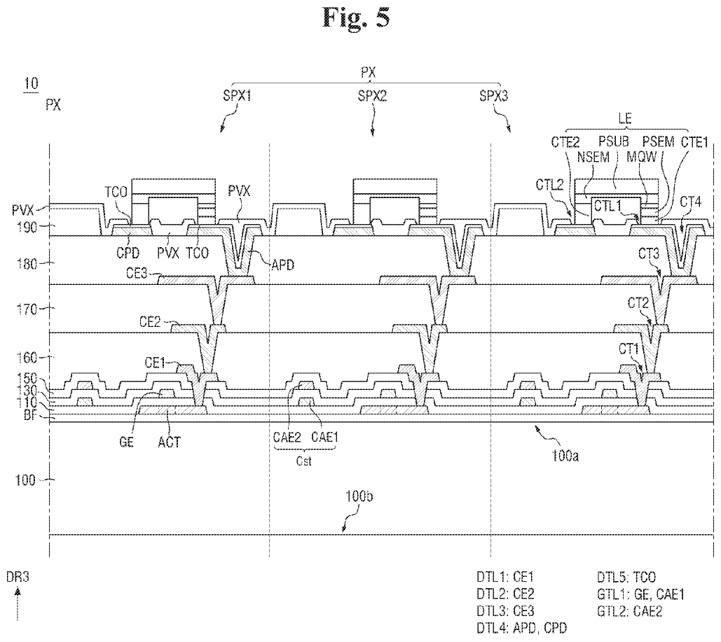

FIG. 3 is a schematic view illustrating a structure of a pixel of the display device according to one or more embodiments. FIG. 4 is a schematic view illustrating a structure of a pixel of a display device according to one or more other embodiments. FIG. 5 is a schematic cross-sectional view illustrating a cross-sectional structure of a pixel according to one or more embodiments.

Referring to FIGS. 3 and 4, each of the pixels PX may include a plurality of sub-pixels. It has been illustrated in FIGS. 3 and 4 that each of the pixels PX includes three sub-pixels SPX1, SPX2, and SPX3, that is, a first sub-pixel SPX1, a second sub-pixel SPX2, and a third sub-pixel SPX3, but the number of sub-pixels is not limited thereto. Each of the first sub-pixel SPX1, the second sub-pixel SPX2, and the third sub-pixel SPX3 may be connected to any one of data lines and at least one of scan lines.

Each of the first sub-pixel SPX1, the second sub-pixel SPX2, and the third sub-pixel SPX3 may have a rectangular shape, a square shape, or a rhombic shape in plan view. For example, each of the first sub-pixel SPX1, the second sub-pixel SPX2, and the third sub-pixel SPX3 may have a rectangular shape, in plan view, having long sides in the first direction DR1 and short sides in the second direction DR2, as illustrated in FIG. 3. Alternatively, each of the first sub-pixel SPX1, the second sub-pixel SPX2, and the third sub-pixel SPX3 may have a square shape or a rhombic shape, in plan view, including sides having the same length in the first direction DR1 and the second direction DR2, as illustrated in FIG. 4.

The first sub-pixel SPX1, the second sub-pixel SPX2, and the third sub-pixel SPX3 may be arranged in the second direction DR2. Alternatively, the first sub-pixel SPX1 and any one of the second sub-pixel SPX2 and the third sub-pixel SPX3 may be arranged in the second direction DR2, and the first sub-pixel SPX1 and the other of the second sub-pixel SPX2 and the third sub-pixel SPX3 may be arranged in the first direction DR1. For example, as illustrated in FIG. 4, the first sub-pixel SPX1 and the second sub-pixel SPX2 may be arranged in the second direction DR2, and the first sub-pixel SPX1 and the third sub-pixel SPX3 may be arranged in the first direction DR1.

The first sub-pixel SPX1 may emit first light, the second sub-pixel SPX2 may emit second light, and the third sub-pixel SPX3 may emit third light. In this case, the first light may be light of a red wavelength band, the second light may be light of a green wavelength band, and the third light may be light of a blue wavelength band. The red wavelength band may be a wavelength band of about 600 nm to about 750 nm, the green wavelength band may be a wavelength band of about 480 nm to about 560 nm, and the blue wavelength band may be a wavelength band of about 370 nm to about 460 nm, but one or more embodiments of the disclosure is not limited thereto.

Each of the first sub-pixel SPX1, the second sub-pixel SPX2, and the third sub-pixel SPX3 may include an inorganic light emitting element including an inorganic semiconductor as a light emitting element LE (see FIG. 5) for emitting light. For example, the inorganic light emitting element may be a flip chip-type micro light emitting diode (LED), but is not limited thereto.

As illustrated in FIGS. 3 and 4, an area of the first sub-pixel SPX1, an area of the second sub-pixel SPX2, and an area of the third sub-pixel SPX3 may be substantially the same as each other, but are not limited thereto. For example, an area of the first sub-pixel SPX1, an area of the second sub-pixel SPX2, and an area of the third sub-pixel SPX3 may also be different from each other.

Referring to FIG. 5, each of the plurality of sub-pixels SPX1, SPX2, and SPX3 constituting the pixel PX may include a plurality of conductive layers, a plurality of insulating layers, and a plurality of light emitting elements LE. The plurality of conductive layers and the plurality of insulating layers may form a transistor layer for transferring electric signals to the light emitting elements LE.

The plurality of sub-pixels located on the substrate 100 include an active layer ACT, a first gate metal layer GTL1, a second gate metal layer GTL2, a first data metal layer DTL1, a second data metal layer DTL2, a third data metal layer DTL3, a fourth data metal layer DTL4, and a fifth data metal layer DTL5 as the plurality of conductive layers. In addition, the plurality of pixels PX include a buffer layer BF, a gate insulating layer 110, a first interlayer insulating layer 130, a second interlayer insulating layer 150, and an upper via layer as the plurality of insulating layers and including a first via layer 160, a second via layer 170, a third via layer 180, and a fourth via layer 190.

The substrate 100 may serve as a base of the display device 10, and may be a base substrate or a base member for supporting the plurality of pixels PX. As described above, the substrate 100 may be a rigid substrate made of a glass material.

The buffer layer BF may be located on the upper surface, that is, the first surface 100a, of the substrate 100. The buffer layer BF may serve to reduce or prevent air or moisture from permeating into element layers constituting the pixel PX. The buffer layer BF may include a plurality of inorganic films that are alternately stacked. For example, the buffer layer BF may be formed as multiple films in which one or more inorganic films of a silicon nitride layer, a silicon oxynitride layer, a silicon oxide layer, a titanium oxide layer, and an aluminum oxide layer are alternately stacked. In some embodiments, the buffer layer BF may be omitted.

The active layer ACT may be located on the buffer layer BF. The active layer ACT may include a silicon semiconductor, such as polycrystalline silicon, single crystal silicon, low-temperature polycrystalline silicon, and amorphous silicon or include an oxide semiconductor.

The active layer ACT may include a channel region, a first region located on one side of the channel region, and a second region located on the other side of the channel region. The channel region of the active layer ACT may be a region overlapping a gate electrode GE, which is to be described later, in the third direction DR3. Each of the first region and the second region of the active layer ACT may be a region that does not overlap the gate electrode GE. The first region and the second region may be regions having conductivity by doping a silicon semiconductor or an oxide semiconductor with ions.

The gate insulating layer 110 may be located on the active layer ACT. The gate insulating layer 110 may be formed as an inorganic film, for example, a silicon nitride layer, a silicon oxynitride layer, a silicon oxide layer, a titanium oxide layer, or an aluminum oxide layer.

The first gate metal layer GTL1 may be located on the gate insulating layer 110. The first gate metal layer GTL1 may include a gate electrode GE and a first capacitor electrode CAE1 of each sub-pixel. The gate electrode GE may form a thin film transistor for driving the pixel PX together with the active layer ACT. The first gate metal layer GTL1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first interlayer insulating layer 130 may be located on the first gate metal layer GTL1. The first interlayer insulating layer 130 may be formed as an inorganic film, for example, a silicon nitride layer, a silicon oxynitride layer, a silicon oxide layer, a titanium oxide layer, or an aluminum oxide layer.

The second gate metal layer GTL2 may be located on the first interlayer insulating layer 130. The second gate metal layer GTL2 may include a second capacitor electrode CAE2. The second capacitor electrode CAE2 may overlap the first capacitor electrode CAE1 in the third direction DR3 to form a capacitor Cst. The second gate metal layer GTL2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second interlayer insulating layer 150 may be located on the second gate metal layer GTL2. The second interlayer insulating layer 150 may be formed as an inorganic film, for example, a silicon nitride layer, a silicon oxynitride layer, a silicon oxide layer, a titanium oxide layer, or an aluminum oxide layer.

The first data metal layer DTL1 including a first connection electrode CE1 and a data line may be located on the second interlayer insulating layer 150. The first data metal layer DTL1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first connection electrode CE1 may be connected to the first region or the second region of the active layer ACT through a first contact hole CT1 penetrating through the first interlayer insulating layer 130 and the second interlayer insulating layer 150.

The first via layer 160 for planarizing a step due to the active layer ACT, the first gate metal layer GTL1, the second gate metal layer GTL2, and the first data metal layer DTL1 may be located on the first data metal layer DTL1. The first via layer 160 may be formed as an organic film made of an acrylic resin, an epoxy resin, a phenolic resin, a polyamide resin, a polyimide resin, or the like.

The second data metal layer DTL2 may be located on the first via layer 160. The second data metal layer DTL2 may include a second connection electrode CE2. The second connection electrode CE2 may be connected to the first connection electrode CE1 through a second contact hole CT2 penetrating through the first via layer 160. The second data metal layer DTL2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second via layer 170 may be located on the second data metal layer DTL2. The second via layer 170 may be formed as an organic film made of an acrylic resin, an epoxy resin, a phenolic resin, a polyamide resin, a polyimide resin, or the like.

The third data metal layer DTL3 may be located on the second via layer 170. The third data metal layer DTL3 may include a third connection electrode CE3. The third connection electrode CE3 may be connected to the second connection electrode CE2 through a third contact hole CT3 penetrating through the second via layer 170. The third data metal layer DTL3 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The third via layer 180 may be located on the third data metal layer DTL3. The third via layer 180 may be formed as an organic film made of an acrylic resin, an epoxy resin, a phenolic resin, a polyamide resin, a polyimide resin, or the like.

The fourth data metal layer DTL4 may be located on the third via layer 180. The fourth data metal layer DTL4 may include an anode pad electrode APD and a cathode pad electrode CPD. The anode pad electrode APD may be connected to the third connection electrode CE3 through a fourth contact hole CT4 penetrating through the third via layer 180. The cathode pad electrode CPD may receive a first source voltage, which may be a low potential voltage. The fourth data metal layer DTL4 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The fifth data metal layer DTL5 may be located on each of the anode pad electrode APD and the cathode pad electrode CPD. The fifth data metal layer DTL5 may include a transparent conductive layer TCO for increasing an adhesive force with a first contact electrode CTE1 and a second contact electrode CTE2 of the light emitting element LE. The fifth data metal layer DTL5 may be formed of a transparent conductive oxide, such as indium tin oxide (ITO) and indium zinc oxide (IZO).

The fourth via layer 190 may be further located on the third via layer 180. The fourth via layer 190 may be located in a space between the plurality of sub-pixels spaced apart from each other. In other words, the fourth via layer 190 is not entirely located on the third via layer 180, and may be partially located on the third via layer 180. That is, the fourth via layer 190 may serve as a pixel defining film dividing the sub-pixels. The fourth via layer 190 may be formed as an organic film made of an acrylic resin, an epoxy resin, a phenolic resin, a polyamide resin, a polyimide resin, or the like.

An upper passivation layer PVX may be located on the third via layer 180, the fifth data metal layer DTL5, and the fourth via layer 190. The upper passivation layer PVX may cover respective edges of a transparent conductive layer TCO located on the anode pad electrode APD and a transparent conductive layer TCO located on the cathode pad electrode CPD, and may cover an upper surface and side surfaces of the fourth via layer 190 and an upper surface of the third via layer 180 exposed by the fourth via layer 190. The upper passivation layer PVX may be formed as an inorganic film, for example, a silicon nitride layer, a silicon oxynitride layer, a silicon oxide layer, a titanium oxide layer, or an aluminum oxide layer.

A first element contact hole CTL1 and a second element contact hole CTL2 exposing respective portions of the transparent conductive layer TCO located on the anode pad electrode APD and the transparent conductive layer TCO located on the cathode pad electrode CPD may be formed in the upper passivation layer PVX. The first element contact hole CTL1 may expose a portion of the transparent conductive layer TCO located on the anode pad electrode APD, and the second element contact hole CTL2 may expose a portion of the transparent conductive layer TCO located on the cathode pad electrode CPD.

Each of the plurality of sub-pixels SPX1, SPX2, and SPX3 may include one light emitting element LE. The light emitting elements LE may be located on the transparent conductive layer TCO located on the anode pad electrode APD and the transparent conductive layer TCO located on the cathode pad electrode CPD, which are respectively exposed by the first element contact hole CTL1 and the second element contact hole CTL2 formed in the upper passivation layer PVX. It has been illustrated in FIG. 5 that the light emitting element LE is a flip chip-type micro LED in which the first contact electrode CTE1 and the second contact electrode CTE2 are located to face the anode pad electrode APD and the cathode pad electrode CPD, respectively.

The light emitting element LE may be an inorganic light emitting element made of an inorganic material, such as GaN. Each of lengths of the light emitting element LE in the first direction DR1, the second direction DR2, and the third direction DR3 may be several to several hundred micrometers. For example, each of lengths of the light emitting element LE in the first direction DR1, the second direction DR2, and the third direction DR3 may be about 100 μm or less.

The light emitting elements LE may be grown and formed on a semiconductor substrate, such as a silicon wafer. Each of the light emitting elements LE may be directly transferred from the silicon wafer onto the anode pad electrode APD and the cathode pad electrode CPD of the substrate 100. Alternatively, each of the light emitting elements LE may be transferred onto the anode pad electrode APD and the cathode pad electrode CPD of the substrate 100 through an electrostatic method using an electrostatic head or a stamp method using an elastic polymer material, such as polydimethylsiloxane (PDMS) or silicon as a material of a transfer substrate.

Each of the light emitting element LE may be a light emitting structure including a base substrate PSUB, an n-type semiconductor NSEM, an active layer MQW, a p-type semiconductor PSEM, the first contact electrode CTE1, and the second contact electrode CTE2.

The base substrate PSUB of the light emitting element LE may be a sapphire substrate, but is not limited thereto.

The n-type semiconductor NSEM of the light emitting element LE may be located on one surface of the base substrate PSUB. For example, the n-type semiconductor NSEM may be located on a lower surface of the base substrate PSUB. The n-type semiconductor NSEM may be made of GaN doped with an n-type dopant, such as Si, Ge, or Sn.

The active layer MQW of the light emitting element LE may be located on a portion of one surface of the n-type semiconductor NSEM. The active layer MQW may include a material having a single or multiple quantum well structure. When the active layer MQW includes the material having the multiple quantum well structure, the active layer MQW may have a structure in which a plurality of well layers and barrier layers are alternately stacked. In this case, the well layer may be formed of InGaN, and the barrier layer may be formed of GaN or AlGaN, but the disclosure is not limited thereto.

Alternatively, the active layer MQW may have a structure in which semiconductor materials having large band gap energy and semiconductor materials having small band gap energy are alternately stacked, and may include Group III to Group V semiconductor materials depending on a wavelength band of emitted light.

The p-type semiconductor PSEM may be located on one surface of the active layer MQW. The p-type semiconductor PSEM may be made of GaN doped with a p-type conductivity-type dopant, such as Mg, Zn, Ca, Se, or Ba.

The first contact electrode CTE1 may be located on the p-type semiconductor PSEM. The second contact electrode CTE2 may be located on another portion of the one surface of the n-type semiconductor NSEM, which may be spaced from the portion of the one surface of the n-type semiconductor NSEM on which the active layer MQW is located.

The first contact electrode CTE1 and the anode pad electrode APD may be adhered to each other through a conductive adhesive member, such as an anisotropic conductive film (ACF) or an anisotropic conductive paste (ACP). Alternatively, the first contact electrode CTE1 and the anode pad electrode APD may be adhered to each other through a soldering process.

Hereinafter, an arrangement relationship between the pixels PX and the side wirings 200 and an arrangement relationship between the side wirings 200 and the driver will be described.

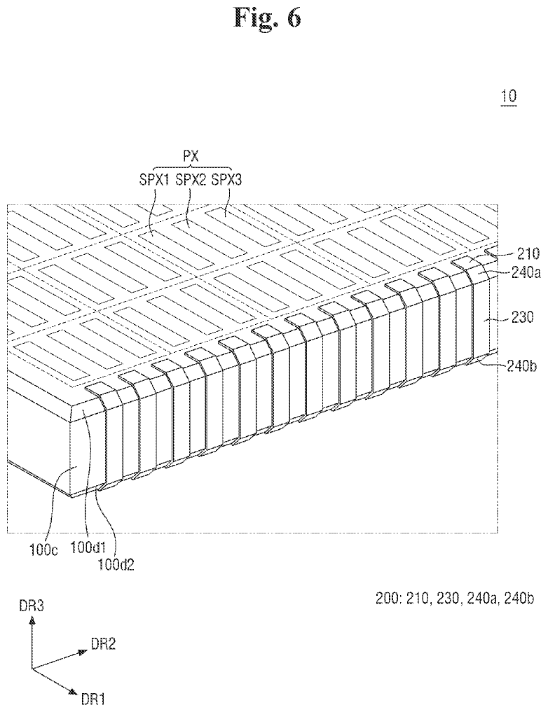

FIG. 6 is a perspective view illustrating an arrangement relationship between pixels and side wirings of the display device according to one or more embodiments FIG. 7 is a plan view illustrating the arrangement relationship between the pixels and the side wirings of the display device according to one or more embodiments. FIG. 8 is a rear view illustrating an arrangement relationship between the side wirings and the driver of the display device according to one or more embodiments.

Referring to FIGS. 6 to 8, the display device 10 further includes a plurality of first pads PAD1, a plurality of second pads PAD2, a plurality of third pads PAD3, and a plurality of lower surface connection lines BCL.

The plurality of first pads PAD1 may serve to transfer electrical signals of the driver to each of the plurality of pixels PX. The first pads PAD1 may be located on the first surface 100a of the substrate 100. The first pads PAD1 may be located at one edge of the first surface 100a of the substrate 100 in the first direction DR1, that is, in a pad area PDA. The pad area PDA is a portion of the non-display area NDA, and may refer to a non-display area NDA located at one edge of the display area DA in the first direction DR1. The first pads PAD1 may be arranged in the second direction DR2.

The plurality of second pads PAD2 may serve to transfer the electrical signals of the driver to the first pads PAD1 through the side wirings 200. The second pads PAD2 may be located on the second surface 100b of the substrate 100. The second pads PAD2 may be located at one edge of the second surface 100b of the substrate 100 in the first direction DR1. The second pads PAD2 may be arranged in the second direction DR2.

The plurality of third pads PAD3 may serve to transfer the electrical signals generated from the driver to the second pads PAD2 through the lower surface connection line BCL. The third pads PAD3 may be located on the second surface 100b of the substrate 100. The third pads PAD3 may be closer to the center of the second surface 100b of the substrate 100 than the second pads PAD2. The third pads PAD3 may be arranged in the second direction DR2. The third pads PAD3 may be arranged to correspond to terminals formed on the driver. In other words, the third pads PAD3 may be arranged to correspond to the terminals formed on the circuit board CB of the driver. To connect more third pads PAD3 to the circuit board CB, an interval between the third pads PAD3 neighboring to each other in the second direction DR2 may be smaller than an interval between the second pads PAD2 neighboring to each other in the second direction DR2.

The plurality of lower surface connection lines BCL may serve to connect the second pads PAD2 and the third pads PAD3 to each other. The interval between the second pads PAD2 neighboring to each other in the second direction DR2 and the interval between the third pads PAD3 neighboring to each other in the second direction DR2 are different from each other, and thus, the lower surface connection lines BCL may be bent at least once. The lower surface connection line BCL may be formed integrally with the second pad PAD2 and the third pad PAD3. Each of the second pad PAD2, the third pad PAD3, and the lower surface connection line BCL may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The side wiring 200 may include a first flat portion 210, a first inclined portion 240a, a connection portion 230, a second inclined portion 240b, and a second flat portion 220.

The first flat portion 210 of the side wiring 200 may be a portion located on the first surface 100a of the substrate 100, for example, the pad area PDA of the first surface 100a. The first flat portion 210 may be located on the first pad PAD1, and may be located to completely cover the first pad PAD1. The first flat portion 210 may be electrically connected to the first pad PAD1.

The first inclined portion 240a of the side wiring 200 may be a portion located on the first chamfered surface 100d1 of the substrate 100. The first inclined portion 240a may form an inclination along a direction in which the first chamfered surface 100d1 is inclined. The first inclined portion 240a may be located between the first flat portion 210 and the connection portion 230.

The connection portion 230 of the side wiring 200 may be a portion located on the first side surface 100c of the substrate 100. The connection portion 230 may be located between the first inclined portion 240a and the second inclined portion 240b.

The second inclined portion 240b of the side wiring 200 may be a portion located on the second chamfered surface 100d2 of the substrate 100. The second inclined portion 240b may form an inclination along a direction in which the second chamfered surface 100d2 is inclined. The second inclined portion 240b may be located between the second flat portion 220 and the connection portion 230.

The second flat portion 220 of the side wiring 200 may be a portion located on the second surface 100b of the substrate 100. The second flat portion 220 may be located on the second pad PAD2, and may be located to completely cover the second pad PAD2. The second flat portion 220 may be electrically connected to the second pad PAD2.

The side wiring 200 may include a metal powder including metal particles, such as silver (Ag) particles and copper (Cu) particles and a polymer, such as an acrylic resin or an epoxy resin. The metal powder may allow the side wiring 200 to have conductivity, and the polymer may serve as a binder binding the metal particles to each other.

The side wiring 200 may be formed by printing a metal paste including metal particles, a monomer, and a solution on the substrate 100 using a silicon pad and then sintering the metal paste using laser beams. In a sintering process of the side wiring 200, the metal particles are in close contact and aggregated with each other while the monomer is converted into a polymer by heat of the laser beams, so that specific resistance of the side wiring 200 may be lowered. The sintering process of the side wiring 200 will be described in detail later.

Hereinafter, a structure of one edge of the display device 10 in the first direction DR1 where a boundary between the display area DA and the pad area PDA is formed, that is, an arrangement structure of the first pads PAD1, the second pads PAD2, the third pads PAD3, and the pixels PX will be described.

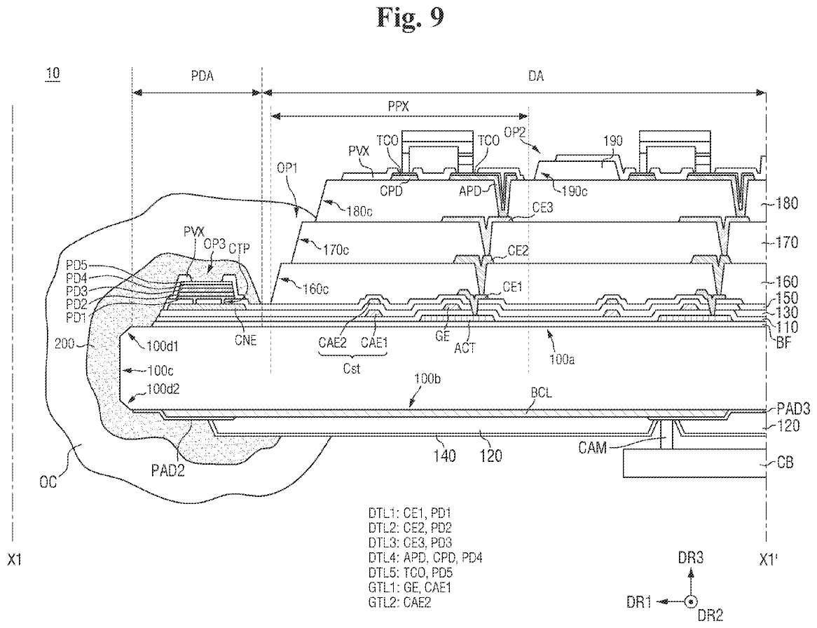

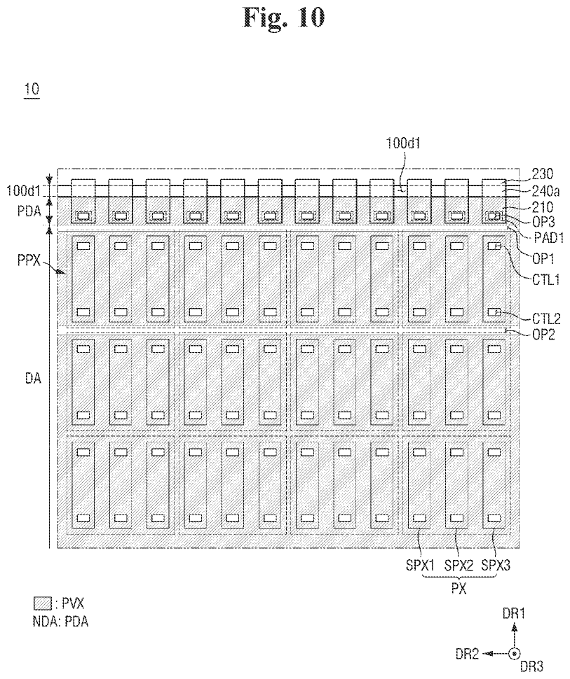

FIG. 9 is a cross-sectional view illustrating a cross section taken along the line X1-X1′ of FIG. 8. FIG. 10 is a plan view illustrating a profile of an upper passivation layer covering an upper surface of a substrate of FIG. 9.

Referring to FIGS. 9 and 10, the first pads PAD1 may be located adjacent to outermost pixels PPX and may be spaced from each other, and the second pads PAD2 may be located on the second surface 100b of the substrate 100.

For convenience of explanation, a sub-pixel located closest to the pad area PDA among the plurality of sub-pixels located in the display area DA will be referred to as an outermost pixel PPX′. The outermost pixel PPX is a sub-pixel located at one edge of the display area DA in the first direction DR1, and a sub-pixel adjacent to the outermost pixel PPX is located only on the other side of the outermost pixel PPX in the first direction DR1, and is not located on the one side of the outermost pixel PPX in the first direction DR1. Accordingly, the fourth via layer 190 may not be located on one side of the outermost pixel PPX in the first direction DR1, and the fourth via layer 190 may be located on the other side of the outermost pixel PPX in the first direction DR1. For convenience of explanation, the fourth via layer 190 located on the other side of the outermost pixel PPX in the first direction DR1 will be referred to as an outermost fourth via layer 190.

A configuration of the outermost pixel PPX is the same as that of the sub-pixel described above with reference to FIG. 5, and a description thereof will thus be omitted.

In the pad area PDA, the first data metal layer DTL1 may further include a first upper pad electrode PD1, the second data metal layer DTL2 may further include a second upper pad electrode PD2, the third data metal layer DTL3 may further include a third upper pad electrode PD3, the fourth data metal layer DTL4 may further include a fourth upper pad electrode PD4, and the fifth data metal layer DTL5 may further include a fifth upper pad electrode PD5.

The first pad PAD1 may include the first upper pad electrode PD1, the second upper pad electrode PD2, the third upper pad electrode PD3, the fourth upper pad electrode PD4, and the fifth upper pad electrode PD5. The second upper pad electrode PD2 may be located on the first upper pad electrode PD1, the third upper pad electrode PD3 may be located on the second upper pad electrode PD2, the fourth upper pad electrode PD4 may be located on the third upper pad electrode PD3, and the fifth upper pad electrode PD5 may be located on the fourth upper pad electrode PD4. An upper surface of the first upper pad electrode PD1 may be in direct contact with a lower surface of the second upper pad electrode PD2, an upper surface of the second upper pad electrode PD2 may be in direct contact with a lower surface of the third upper pad electrode PD3, an upper surface of the third upper pad electrode PD3 may be in direct contact with a lower surface of the fourth upper pad electrode PD4, and an upper surface of the fourth upper pad electrode PD4 may be in direct contact with a lower surface of the fifth upper pad electrode PD5.

The first upper pad electrode PD1 of the first pad PAD1 may be located on the second interlayer insulating layer 150. The first upper pad electrode PD1 may be electrically connected to an upper surface connection line CNE located on the first interlayer insulating layer 130 through a pad contact hole CTP penetrating through the second interlayer insulating layer 150. The upper surface connection line CNE may be electrically connected to the above-described data line.

The lower surface connection line BCL may be located to extend in the first direction DR1 on the second surface 100b of the substrate 100. The lower surface connection line BCL may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second pad PAD2 may be located on the second surface 100b of the substrate 100. The second pad PAD2 may be located on one side of the lower surface connection line BCL in the first direction DR1, and the third pad PAD3 may be located on the other side of the lower surface connection line BCL in the first direction DR1. The second pad PAD2 and the third pad PAD3 may be formed of a transparent conductive oxide, such as indium tin oxide (ITO) and indium zinc oxide (IZO).

A lower via layer 120 may be located on the second surface 100b of the substrate 100. For example, the lower via layer 120 may be located on the other side surface of the lower surface connection line BCL in the third direction DR3. The lower via layer 120 may partially cover the second pad PAD2 and the third pad PAD3, but may expose at least portions of the second pad PAD2 and the third pad PAD3. A portion of the second pad PAD2 exposed by the lower via layer 120 may be in direct contact with, and electrically connected to, the second flat portion 220 of the side wiring 200, and a portion of the third pad PAD3 exposed by the lower via layer 120 may be electrically connected to the circuit board CB by a conductive adhesive member CAM. The conductive adhesive member CAM may be an anisotropic conductive film or an anisotropic conductive paste.

The lower via layer 120 may be formed as an organic film made of an acrylic resin, an epoxy resin, a phenolic resin, a polyamide resin, a polyimide resin, or the like.

A lower passivation layer 140 may cover the lower via layer 120. For example, the lower passivation layer 140 may be located on the lower via layer 120, but might not be located on the second pad PAD2 and the third pad PAD3. In other words, each of the second pad PAD2 and the third pad PAD3 may include a portion exposed by the lower passivation layer 140. The lower passivation layer 140 may be formed as an inorganic film, for example, a silicon nitride layer, a silicon oxynitride layer, a silicon oxide layer, a titanium oxide layer, or an aluminum oxide layer.

The side wiring 200 may be located on the first surface 100a, the first chamfered surface 100d1, the first side surface 100c, the second chamfered surface 100d2, and the second surface 100b of the substrate 100. The side wiring 200 may be located on, and electrically connected to, the first pad PAD1 located at one edge of the first surface 100a of the substrate 100 in the first direction DR1. The side wiring 200 may be located on, and connected to, the second pad PAD2 located at one edge of the second surface 100b of the substrate 100 in the first direction DR1. The side wiring 200 may be in contact with the first chamfered surface 100d1, the first side surface 100c, and the second chamfered surface 100d2 of the substrate 100.

An overcoat layer OC may be located on, or close to, the first surface 100a, the first chamfered surface 100d1, the first side surface 100c, the second chamfered surface 100d2, and the second surface 100b of the substrate 100. The overcoat layer OC may be located to cover the side wiring 200. The overcoat layer OC may be formed as an organic film made of an acrylic resin, an epoxy resin, a phenolic resin, a polyamide resin, a polyimide resin, or the like.

Meanwhile, the first via layer 160, the second via layer 170, and the third via layer 180 extending in the first direction DR1 in the display area DA may not extend in the vicinity of the boundary between the display area DA and the pad area PDA. In other words, the first via layer 160, the second via layer 170, and the third via layer 180 no longer extend in the vicinity of the outermost pixel PPX, and sidewalls 160c, 170c, and 180c in the first direction DR1 may be formed.

For example, the first via layer 160 no longer extends in the first direction DR1 in the vicinity of the boundary between the display area DA and the pad area PDA, and may be finished by (e.g., may terminate at) a first via sidewall 160c. The second via layer 170 no longer extends in the first direction DR1 in the vicinity of the boundary between the display area DA and the pad area PDA, and may be finished by a second via sidewall 170c. The third via layer 180 no longer extends in the first direction DR1 in the vicinity of the boundary between the display area DA and the pad area PDA, and may be finished by a third via sidewall 180c. In other words, one sidewall of the first via layer 160 in the first direction DR1 may be referred to as the first via sidewall 160c, one sidewall of the second via layer 170 in the first direction DR1 may be referred to as the second via sidewall 170c, and one sidewall of the third via layer 180 in the first direction DR1 may be referred to as the third via sidewall 180c.

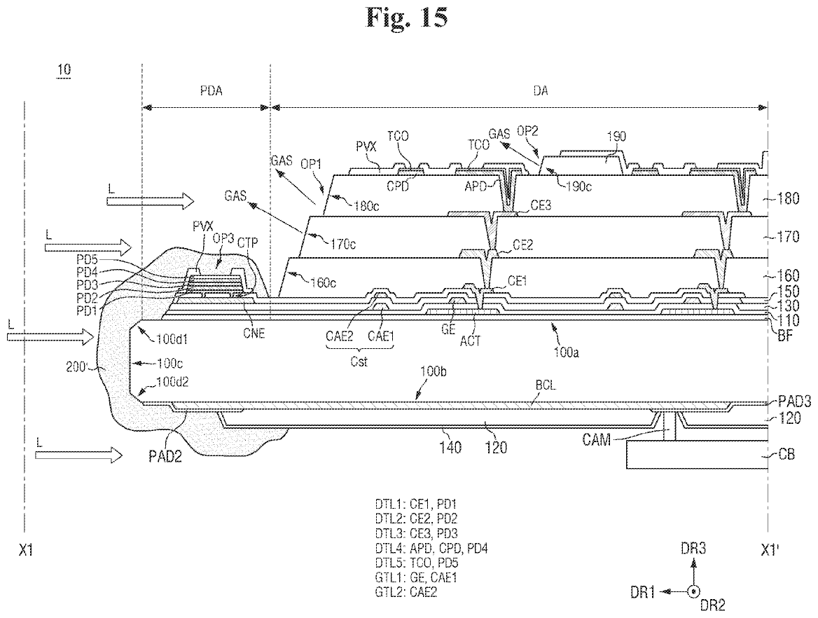

The upper passivation layer PVX may expose one side surface, in the first direction DR1, of the upper via layer including the first via layer 160, the second via layer 170, and the third via layer 180, that is, a side surface facing the first pad PAD1, through a first exposure opening OP1. In other words, the upper passivation layer PVX no longer extends in the vicinity of the boundary between the display area DA and the pad area PDA, and may include the first exposure opening OP1 formed to expose the first via sidewall 160c, the second via sidewall 170c, and the third via sidewall 180c. This may be for discharging an exhaust gas GAS (see FIG. 15) that may be generated in a manufacturing method of a display device. A detailed description thereof will be provided later.

For example, the first exposure opening OP1 of the upper passivation layer PVX may expose the first via sidewall 160c of the first via layer 160, an upper surface of the first via layer 160 exposed by the second via layer 170, the second via sidewall 170c of the second via layer 170, an upper surface of the second via layer 170 exposed by the third via layer 180, and the third via sidewall 180c of the third via layer 180. It has been illustrated in FIG. 9 that the first exposure opening OP1 exposes the entirety of the first via sidewall 160c of the first via layer 160, an upper surface of the first via layer 160 exposed by the second via layer 170, the second via sidewall 170c of the second via layer 170, an upper surface of the second via layer 170 exposed by the third via layer 180, and the third via sidewall 180c of the third via layer 180.

The first exposure opening OP1 may have a shape in which it extends in the second direction DR2 in plan view, as illustrated in FIG. 10, but a shape of the first exposure opening OP1 in plan view is not limited thereto. It has been illustrated in FIG. 10 that the first exposure opening OP1 has a shape in which it extends in the second direction DR2 to correspond to an arrangement of the plurality of side wirings 200.

The upper passivation layer PVX may include a second exposure opening OP2 formed to expose one sidewall 190c of the outermost fourth via layer 190 in the first direction DR1. In other words, the second exposure opening OP2 of the upper passivation layer PVX may expose a side surface of the outermost fourth via layer 190 adjacent to the first pad PAD1. This may be for discharging an exhaust gas GAS (see FIG. 15) that may be generated in a manufacturing method of a display device. A detailed description thereof will be provided later.

The second exposure opening OP2 may have a shape in which it extends in the second direction DR2 in plan view, as illustrated in FIG. 10, but a shape of the second exposure opening OP2 in plan view is not limited thereto. It has been illustrated in FIG. 10 that the second exposure opening OP2 has a shape in which it extends side by side in the second direction DR2 to correspond to an arrangement of the plurality of side wirings 200.

The upper passivation layer PVX may include a third exposure opening OP3 formed to expose an upper surface of the fifth upper pad electrode PD5 of the first pad PAD1. The third exposure opening OP3 may also be referred to as a pad opening. The first flat portion 210 of the side wiring 200 may be electrically connected to the first pad PAD1 through the third exposure opening OP3.

The side wiring 200 might not directly contact the first via sidewall 160c, the second via sidewall 170c, or the third via sidewall 180c exposed by the first exposure opening OP1. For example, the side wiring 200 may cover the first pad PAD1, and may be in direct contact with the second interlayer insulating layer 150 in a space between the first pad PAD1 and the upper via layer spaced apart from each other in the first direction DR1. This may be for discharging an exhaust gas GAS (see FIG. 15) that may be generated in a manufacturing method of a display device. A detailed description thereof will be provided later.

The overcoat layer OC may cover the side wiring 200, and may be in direct contact with the first via sidewall 160c, the second via sidewall 170c, and the third via sidewall 180c exposed by the first exposure opening OP1. In some embodiments, the overcoat layer OC may entirely cover the first via sidewall 160c and the second via sidewall 170c while partially covering the third via sidewall 180c, but is not limited thereto. For example, the overcoat layer OC may entirely cover the first via sidewall 160c, the second via sidewall 170c, and the third via sidewall 180c. The overcoat layer OC may be formed after an exhaust gas GAS is exhausted in a manufacturing process of a display device 10 to be described later.

With the configuration as described above, in the display device 10 according to one or more embodiments, the exhaust gas GAS that may be generated in the manufacturing process of the display device 10 may be exhausted through the first exposure opening OP1 or the second exposure opening OP2, such that a bubble phenomenon may be reduced or prevented, and accordingly, reliability of the display device 10 may be improved.

Hereinafter, a manufacturing method of the display device 10 according to one or more embodiments will be described.

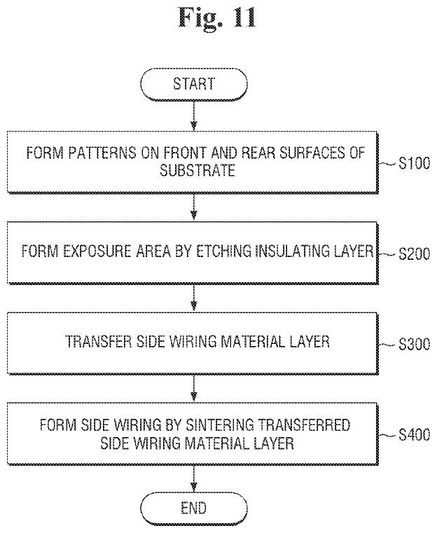

FIGS. 11 to 16 are a flow chart and views for describing a manufacturing method of the display device according to one or more embodiments.

Referring to FIG. 11, a manufacturing method of the display device 10 according to one or more embodiments may include forming patterns on front and rear surfaces of the substrate 100 (S100), forming an exposure area by etching an insulating layer (upper passivation layer PVX) (S200), transferring a side wiring material layer 200′ (S300), and forming a side wiring 200 by sintering the transferred side wiring material layer 200′ (S400).

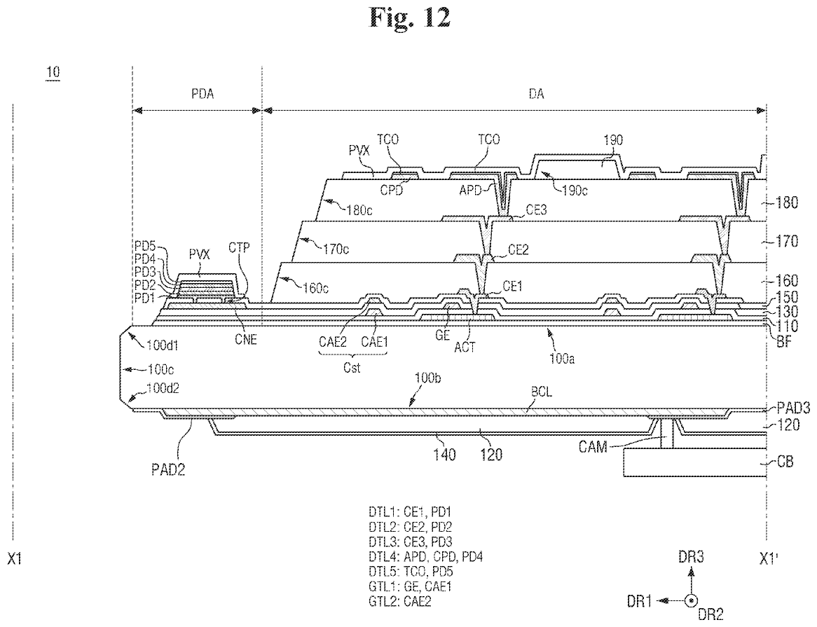

First, referring to FIG. 12, the patterns are formed on the front and rear surfaces of the substrate 100 of the display device 10 (S100). The buffer layer BF, the gate insulating layer 110, the first interlayer insulating layer 130, the second interlayer insulating layer 150, the upper via layer, the upper passivation layer PVX, the active layer ACT, the first gate metal layer GTL1, the second gate metal layer GTL2, the first data metal layer DTL1, the second data metal layer DTL2, the third data metal layer DTL3, the fourth data metal layer DTL4, and the fifth data metal layer DTL5 described above may be located on the front surface, that is, the first surface 100a, of the substrate 100, and the second pad PAD2, the lower via layer 120, and the lower passivation layer 140 described above may be located on the rear surface, that is, the second surface 100b, of the substrate 100. A method of forming the patterns on the front and rear surfaces of the substrate 100 of the display device 10 is well known to one of ordinary skill in the art, and a repeated detailed description thereof will thus be omitted.

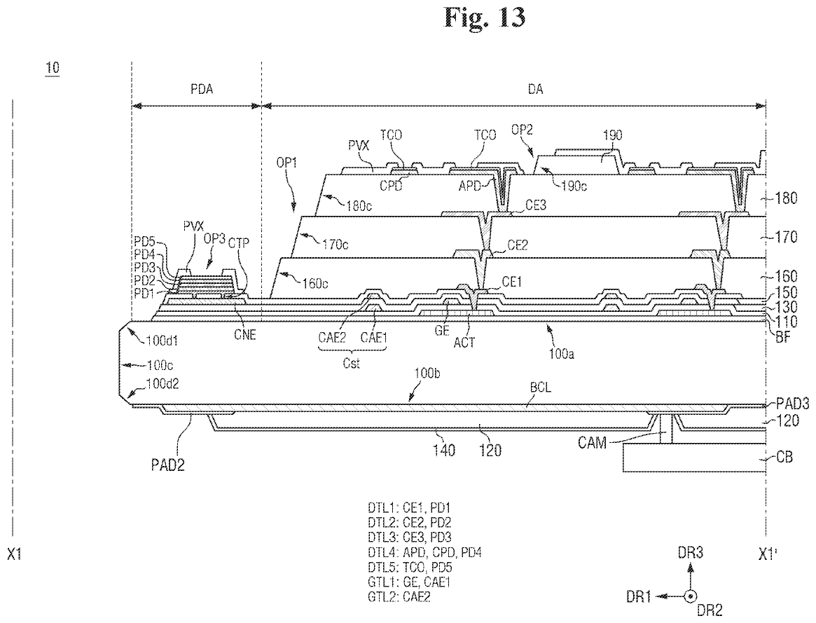

Next, referring to FIG. 13, the exposure area is formed by etching the upper passivation layer PVX among the insulating layers formed on the first surface 100a of the display device 10 (S200). The exposure area may be a concept including the first exposure opening OP1, the second exposure opening OP2, and the third exposure opening OP3 described above.

A process of forming the first exposure openings OP1, the second exposure openings OP2, and the third exposure openings OP3 by etching the upper passivation layer PVX may be performed, for example, by placing a photoresist on areas other than areas corresponding to the first exposure opening OP1, the second exposure opening OP2, and the third exposure opening OP3 of the upper passivation layer PVX, and by etching the upper passivation layer PVX using the photoresist as an etch stop layer.

Accordingly, as described above, the first via sidewall 160c, the second via sidewall 170c, and the third via sidewall 180c may be exposed by the first exposure opening OP1, while one sidewall of the outermost fourth via layer 190 in the first direction DR1 may be exposed by the second exposure opening OP2, and the upper surface of the first pad PAD1 may be exposed by the third exposure opening OP3.

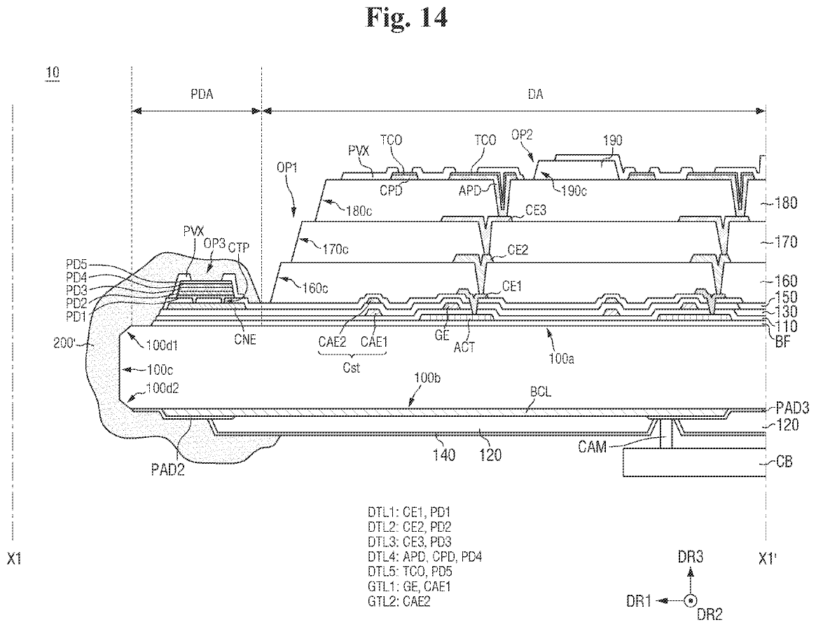

Next, referring to FIG. 14, the side wiring material layer 200′ is transferred to the substrate 100 (S300). The side wiring material layer 200′ includes substantially the same material as the side wiring 200, and when the side wiring material layer 200′ undergoes a sintering process to be described later, the side wiring material layer 200′ will become the side wiring 200.

The side wiring material layer 200′ may be formed by printing the metal paste including the metal particles, the monomer, and the solution on the substrate 100 by the silicon pad, as described above.

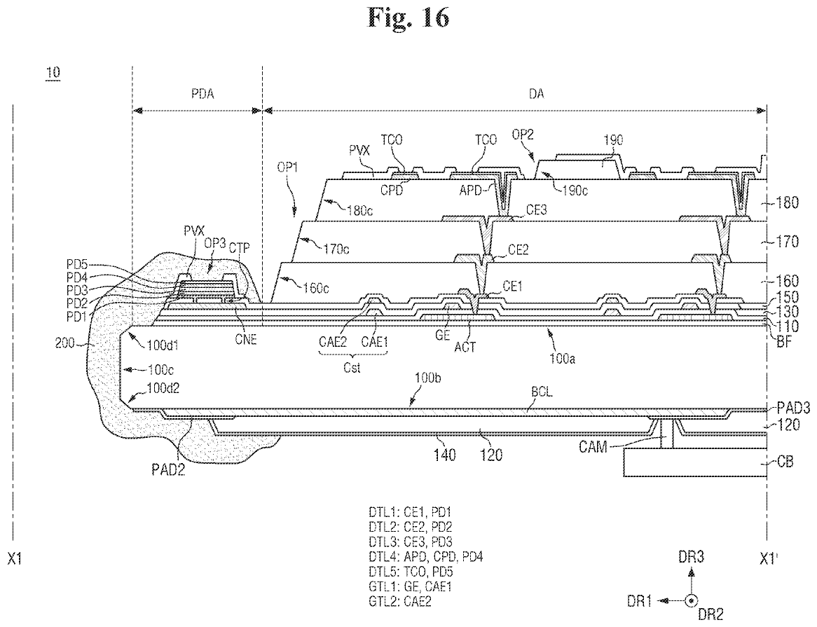

Next, referring to FIGS. 15 and 16, the side wiring 200 is formed by sintering the transferred side wiring material layer 200′ (S400). As described above, the metal particles included in the side wiring material layer 200′ are in close contact and aggregated with each other through the sintering process, such that specific resistance of the side wiring material layer 200′ may be lowered.

A process of sintering the side wiring material layer 200′ may be performed using laser beams L. When the process of sintering the side wiring material layer 200′ is performed using the laser beams L, heat required for sintering the side wiring material layer 200′ is provided in a short period, and thus, a process time may be shortened. However, because the heat required for sintering the side wiring material layer 200′ is provided in the short period, excessive heat may be provided to the upper via layer adjacent to the first pad PAD1, that is, the first via sidewall 160c of the first via layer 160, the second via sidewall 170c of the second via layer 170, the third via sidewall 180c of the third via layer 180, and one sidewall 190c of the outermost fourth via layer 190 in the first direction DR1. Accordingly, the exhaust gas GAS may be discharged from the first via sidewall 160c of the first via layer 160, the second via sidewall 170c of the second via layer 170, the third via sidewall 180c of the third via layer 180, and one sidewall 190c of the outermost fourth via layer 190 in the first direction DR1.

When the upper passivation layer PVX covers the entirety of the first via sidewall 160c of the first via layer 160, the second via sidewall 170c of the second via layer 170, the third via sidewall 180c of the third via layer 180, and one sidewall 190c of the outermost fourth via layer 190 in the first direction DR1 without the first exposure opening OP1 and the second exposure opening OP2, the discharged exhaust gas GAS might not be exhausted, such that a space in which the discharged exhaust gas GAS is collected, that is, a bubble may be formed between the upper passivation layer PVX and the first via sidewall 160c of the first via layer 160, the second via sidewall 170c of the second via layer 170, the third via sidewall 180c of the third via layer 180, and/or one sidewall 190c of the outermost fourth via layer 190 in the first direction DR1. When the bubble is formed, reliability of the display device 10 may decrease, and thus, the decrease in the reliability of the display device 10 may be suitably reduced or prevented.

Accordingly, the first exposure opening OP1 exposing the first via sidewall 160c of the first via layer 160, the second via sidewall 170c of the second via layer 170, and the third via sidewall 180c of the third via layer 180, and the second exposure opening OP2 exposing one sidewall 190c of the outermost fourth via layer 190 in the first direction DR1, are formed in the upper passivation layer PVX to exhaust the exhaust gas GAS discharged in the sintering process, such that generation of the bubble may be reduced or prevented.

Then, a process of forming the light emitting element LE and the overcoat layer OC may be performed to manufacture the display device 10 as illustrated in FIG. 9.

Hereinafter, a structure of a tiled display using the display device 10 according to one or more embodiments will be described.

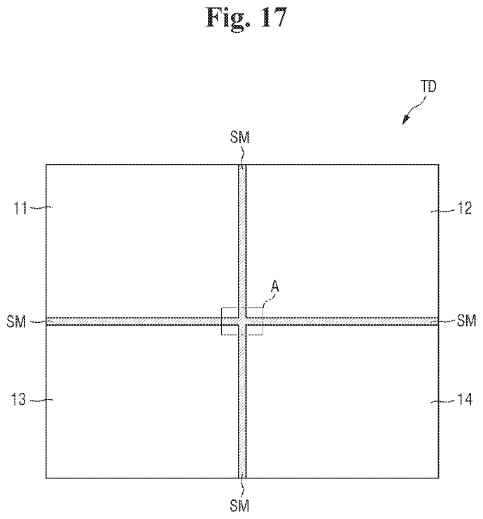

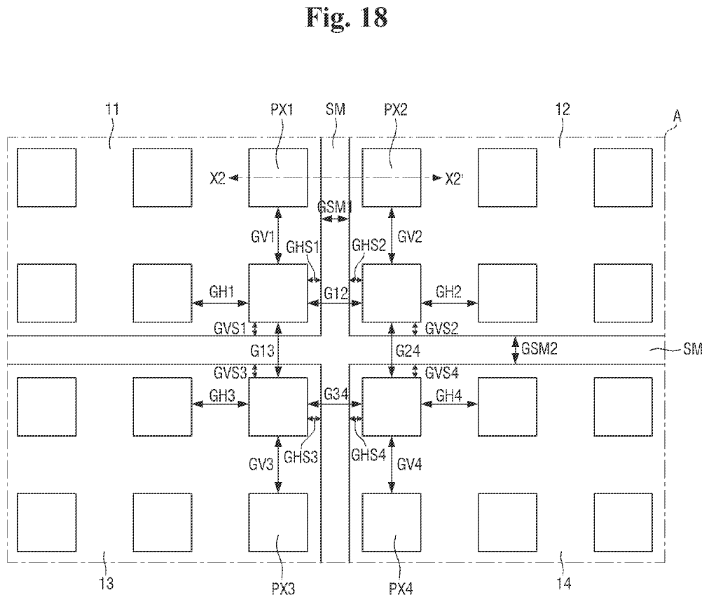

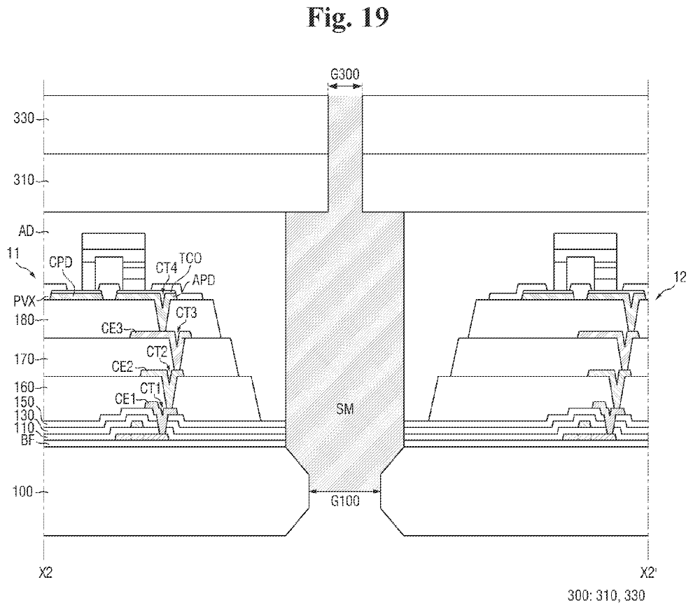

FIG. 17 is a schematic view illustrating a tiled display using the display device according to one or more embodiments. FIG. 18 is an enlarged view of area A of FIG. 17. FIG. 19 is a cross-sectional view illustrating a cross-section taken along the line X2-X2′ of FIG. 18.

Referring to FIGS. 17 to 19, a tiled display TD may include a plurality of display devices 10, seam parts SM, and a front cover 300. For convenience of explanation, according to a relative position relationship between the plurality of display devices 10 illustrated in FIG. 17, a display device 10 positioned on the upper left side will be referred to as a first display device 11, a display device 10 positioned on the upper right side will be referred to as a second display device 12, a display device 10 positioned on the lower left side will be referred to as a third display device 13, and a display device 10 positioned on the lower right side will be referred to as a fourth display device 14. It has been illustrated in FIG. 17 that the tiled display device 10 includes four display devices 10, that is, the first display device 11, the second display device 12, the third display device 13, and the fourth display device 14, but the number of display devices 10 that may be included in the tiled display TD is not limited thereto.

The plurality of display devices 11, 12, 13, and 14 may be arranged in a lattice form. The plurality of display devices 11, 12, 13, and 14 may be arranged in a matrix form in M (M is a positive integer) rows and N (N is a positive integer) columns. It has been illustrated in FIG. 17 that the first display device 11 and the second display device 12 neighbor to each other in the first direction DR1, the first display device 11 and the third display device 13 neighbor to each other in the second direction DR2, the third display device 13 and the fourth display device 14 neighbor to each other in the first direction DR1, and the second display device 12 and the fourth display device 14 neighbor to each other in the second direction DR2, but an arrangement of the plurality of display devices constituting the tiled display TD is not limited thereto. That is, in the tiled display TD, the number and an arrangement of display devices may be determined according to a size of each of the display devices 10 and the tiled display TD and a shape of the tiled display TD. Hereinafter, for convenience of explanation, it will be mainly described that the tiled display TD includes four display devices, and the plurality of display devices 11, 12, 13, and 14 is arranged in two rows and two columns.

The plurality of display devices 11, 12, 13, and 14 constituting the tiled display TD may have the same size, but are not limited thereto. For example, the plurality of display devices 11, 12, 13, and 14 may have different sizes.

Each of the plurality of display devices 11, 12, 13, and 14 may have a rectangular shape having long sides and short sides. The plurality of display devices 11, 12, 13, and 14 may be located with long sides or short sides connected to each other. Some or all of the plurality of display devices 11, 12, 13, and 14 may be located at edges of the tiled display TD and form one side of the tiled display TD. At least one display device 10 of the plurality of display devices 11, 12, 13, and 14 may be located at at least one corner of the tiled display TD, and may form two adjacent sides of the tiled display TD. At least one of the plurality of display devices 11, 12, 13, and 14 may be surrounded by the other display devices.

Each of the plurality of display devices 11, 12, 13, and 14 may be substantially the same as the display device 10 described with reference to FIG. 1. Therefore, a description of each of the plurality of display devices 11, 12, 13, and 14 will be omitted.

The seam parts SM may include coupling members or adhesive members. In this case, the plurality of display devices 11, 12, 13, and 14 may be connected to each other through the coupling members or the adhesive members of the seam parts SM. The seam parts SM may be located between the first display device 11 and the second display device 12, between the first display device 11 and the third display device 13, between the second display device 12 and the fourth display device 14, and between the third display device 13 and the fourth display device 14.

Referring to FIG. 18, the seam part SM may have a cross shape or a plus sign (+) shape in plan view in a central area of the tiled display TD where the first display device 11, the second display device 12, the third display device 13, and the fourth display device 14 are adjacent to each other. The seam parts SM may be located between the first display device 11 and the second display device 12, between the first display device 11 and the third display device 13, between the second display device 12 and the fourth display device 14, and between the third display device 13 and the fourth display device 14.

The first display device 11 may include first pixels PX1 arranged in a matrix form in a row direction (transverse direction based on FIG. 18) and a column direction (longitudinal direction based on FIG. 18) crossing the row direction to display an image. The second display device 12 may include second pixels PX2 arranged in a matrix form in the row direction and the column direction to display an image. The third display device 13 may include third pixels PX3 arranged in a matrix form in the row direction and the column direction to display an image. The fourth display device 14 may include fourth pixels PX4 arranged in a matrix form in the row direction and the column direction to display an image. The first pixel PX1, the second pixel PX2, the third pixel PX3, and the fourth pixel PX4 are substantially the same as the pixel PX of the display device 10 described above, and a detailed description of a structure of each of the first pixel PX1, the second pixel PX2, the third pixel PX3, and the fourth pixel PX4 will thus be omitted.

A minimum distance between the first pixels PX1 neighboring to each other in the first direction DR1 may be defined as a first horizontal spaced distance GH1, and a minimum distance between the second pixels PX2 neighboring to each other in the first direction DR1 may be defined as a second horizontal spaced distance GH2. The first horizontal spaced distance GH1 and the second horizontal spaced distance GH2 may be substantially the same as each other.

The seam part SM may be located between the first pixel PX1 and the second pixel PX2 neighboring to each other in the row direction. A minimum distance G12 between the first pixel PX1 and the second pixel PX2 neighboring to each other in the row direction may be the sum of a minimum distance GHS1 between the first pixel PX1 and the seam part SM in the row direction, a minimum distance GHS2 between the second pixel PX2 and the seam part SM in the row direction, and a width GSM1 of the seam part SM in the row direction.

The minimum distance G12 between the first pixel PX1 and the second pixel PX2 neighboring to each other in the row direction, the first horizontal spaced distance GH1, and the second horizontal spaced distance GH2 may be substantially the same as each other. To this end, the minimum distance GHS1 between the first pixel PX1 and the seam part SM in the row direction may be smaller than the first horizontal spaced distance GH1, and the minimum distance GHS2 between the second pixel PX2 and the seam part SM in the row direction may be smaller than the second horizontal spaced distance GH2. In addition, the width GSM1 of the seam part SM in the row direction may be smaller than the first horizontal spaced distance GH1 or the second horizontal spaced distance GH2.

A minimum distance between the third pixels PX3 neighboring to each other in the row direction may be defined as a third horizontal spaced distance GH3, and a minimum distance between the fourth pixels PX4 neighboring to each other in the row direction may be defined as a fourth horizontal spaced distance GH4. The third horizontal spaced distance GH3 and the fourth horizontal spaced distance GH4 may be substantially the same as each other.

The seam part SM may be located between the third pixel PX3 and the fourth pixel PX4 neighboring to each other in the row direction. A minimum distance G34 between the third pixel PX3 and the fourth pixel PX4 neighboring to each other in the row direction may be the sum of a minimum distance GHS3 between the third pixel PX3 and the seam part SM in the row direction, a minimum distance GHS4 between the fourth pixel PX4 and the seam part SM in the row direction, and a width GSM1 of the seam part SM in the row direction.

The minimum distance G34 between the third pixel PX3 and the fourth pixel PX4 neighboring to each other in the row direction, the third horizontal spaced distance GH3, and the fourth horizontal spaced distance GH4 may be substantially the same as each other. To this end, the minimum distance GHS3 between the third pixel PX3 and the seam part SM in the row direction may be smaller than the third horizontal spaced distance GH3, and the minimum distance GHS4 between the fourth pixel PX4 and the seam part SM in the row direction may be smaller than the fourth horizontal spaced distance GH4. In addition, the width GSM1 of the seam part SM in the row direction may be smaller than the third horizontal spaced distance GH3 or the fourth horizontal spaced distance GH4.

A minimum distance between the first pixels PX1 neighboring to each other in the column direction may be defined as a first vertical spaced distance GV1, and a minimum distance between the third pixels PX3 neighboring to each other in the column direction may be defined as a third horizontal spaced distance GV3. The first vertical spaced distance GV1 and the third vertical spaced distance GV3 may be substantially the same as each other.

The seam part SM may be located between the first pixel PX1 and the third pixel PX3 neighboring to each other in the column direction. A minimum distance G13 between the first pixel PX1 and the third pixel PX3 neighboring to each other in the column direction may be the sum of a minimum distance GVS1 between the first pixel PX1 and the seam part SM in the column direction, a minimum distance GVS3 between the third pixel PX3 and the seam part SM in the column direction, and a width GSM2 of the seam part SM in the row direction.

The minimum distance G13 between the first pixel PX1 and the third pixel PX3 neighboring to each other in the column direction, the first vertical spaced distance GV1, and the third vertical spaced distance GV3 may be substantially the same as each other. To this end, the minimum distance GVS1 between the first pixel PX1 and the seam part SM in the column direction may be smaller than the first vertical spaced distance GV1, and the minimum distance GVS3 between the third pixel PX3 and the seam part SM in the column direction may be smaller than the third vertical spaced distance GV3. In addition, the width GSM2 of the seam part SM in the column direction may be smaller than the first vertical spaced distance GV1 or the third vertical spaced distance GV3.

A minimum distance between the second pixels PX2 neighboring to each other in the column direction may be defined as a second vertical spaced distance GV2, and a minimum distance between the fourth pixels PX4 neighboring to each other in the column direction may be defined as a fourth horizontal spaced distance GV4. The second vertical spaced distance GV2 and the fourth vertical spaced distance GV4 may be substantially the same as each other.

The seam part SM may be located between the second pixel PX2 and the fourth pixel PX4 neighboring to each other in the column direction. A minimum distance G24 between the second pixel PX2 and the fourth pixel PX4 neighboring to each other in the column direction may be the sum of a minimum distance GVS2 between the second pixel PX2 and the seam part SM in the column direction, a minimum distance GVS4 between the fourth pixel PX4 and the seam part SM in the column direction, and a width GSM2 of the seam part SM in the row direction.

The minimum distance G24 between the second pixel PX2 and the fourth pixel PX4 neighboring to each other in the column direction, the second vertical spaced distance GV2, and the fourth vertical spaced distance GV4 may be substantially the same as each other. To this end, the minimum distance GVS2 between the second pixel PX2 and the seam part SM in the column direction may be smaller than the second vertical spaced distance GV2, and the minimum distance GVS4 between the fourth pixel PX4 and the seam part SM in the column direction may be smaller than the fourth vertical spaced distance GV4. In addition, the width GSM2 of the seam part SM in the column direction may be smaller than the second vertical spaced distance GV2 or the fourth vertical spaced distance GV4.

To reduce or prevent the seam parts SM from being viewed between images displayed by the plurality of display devices 11, 12, 13, and 14, as illustrated in FIG. 18, a minimum distance between pixels PX of the display devices 10 neighboring to each other may be substantially the same as a minimum distance between pixels PX of each of the display devices 10.

Referring to FIG. 19, a plurality of front covers 300 may be located on each of the plurality of display devices 11, 12, 13 and 14. For convenience of explanation, the front cover 300 located on the first display device 11 will be referred to as a first front cover, the front cover 300 located on the second display device 12 will be referred to as a second front cover, the front cover 300 located on the third display device 13 will be referred to as a third front cover, and the front cover 300 located on the fourth display device 14 will be referred to as a fourth front cover. The plurality of display devices 11, 12, 13, and 14 and the plurality of front covers 300 corresponding to the plurality of display devices 11, 12, 13, and 14 may be adhered to each other through adhesive members AD. FIG. 19 has illustrated arrangement structures of the first display device 11 and the second display device 12 and the first front cover and the second front cover respectively corresponding to the first display device 11 and the second display device 12. Arrangement structures of the third display device 13 and the third front cover and the fourth display device 14 and the fourth front cover are substantially the same as the arrangement structures of the first display device 11 and the second display device 12 and the first front cover and the second front cover corresponding to the first display device 11 and the second display device 12. Therefore, hereinafter, the first front cover and the second front cover will be mainly described, and a detailed description of the third front cover and the fourth front cover will be omitted.

The first front cover may be located on the first display device 11 to protrude from the substrate 100 of the first display device 11. Therefore, a gap G100 between the substrate 100 of the first display device 11 and the substrate 100 of the second display device 12 may be greater than a gap G300 between the first front cover and the second front cover.

Each of the plurality of front covers 300 may include a light transmittance adjusting layer 310 and an anti-glare layer 330.

As described above, each of the plurality of front covers 300 may be adhered to the corresponding display device 10 by the adhesive member AD. The adhesive member AD may be a transparent adhesive member capable of transmitting light. For example, the adhesive member AD may be an optically clear adhesive film or an optically clear resin.

The light transmittance adjusting layer 310 may be located on the adhesive member AD. The light transmittance adjusting layer 310 may be designed to reduce transmittance of external light or light reflected from the first display device 11 and the second display device 12. In addition, because the front cover 300 protrudes from the substrate 100 as described above, the light transmittance adjusting layer 310 included in the front cover 300 may also protrude from the substrate 100. Accordingly, visibility of the gap G100 between the substrate 100 of the first display device 11 and the substrate 100 of the second display device 12 may be reduced or prevented (e.g., from the outside).

The anti-glare layer 330 may be located on the light transmittance adjusting layer 310. The anti-glare layer 330 may be designed to diffusely reflect external light to reduce or prevent deterioration of visibility of an image by reflecting the external light as it is. Accordingly, a contrast ratio of images displayed by the first display device 11 and the second display device 12 may be increased due to the anti-glare layer 330.

The anti-glare layer 330 may be implemented as a polarizing plate, and the light transmittance adjusting layer 310 may be implemented as a phase delay layer, but one or more embodiments of the disclosure is not limited thereto.

Hereinafter, a driving method of the tiled display TD according to one or more embodiments will be described.

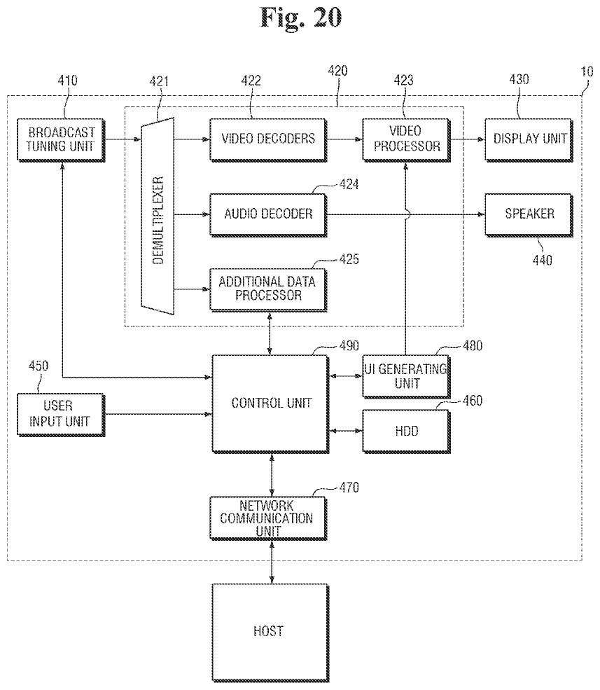

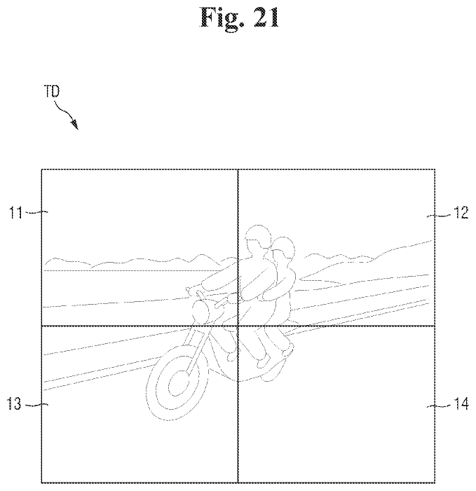

FIG. 20 is a block diagram illustrating a structure of the tiled display according to one or more embodiments. FIG. 21 is a view illustrating a state in which the tiled display using the display device according to one or more embodiments is driven.

Referring to FIGS. 20 and 21, the tiled display TD according to one or more embodiments may include a host system HOST, and a broadcast tuner 410, a signal processor 420, a display 430, a speaker 440, a user interface (e.g., a user input unit) 450, a storage (e.g., a hard disk drive (HDD)) 460, a network communicator 470, a user interface (UI) generator 480, and a controller 490, which are included in each of the plurality of display devices 11, 12, 13, and 14. FIG. 20 has illustrated the host system HOST and the first display device 11.

The host system HOST may be implemented as any one of a television system, a home theater system, a set-top box, a navigation system, a digital versatile disk (DVD) player, a Blu-ray™ player, a personal computer (PC), a mobile phone system, and a tablet PC.

User's commands may be input to the host system HOST in various formats. For example, a command may be input to the host system HOST by a user's touch input. Alternatively, a user's command may be input to the host system HOST by a keyboard input or a button input of a remote controller.

The host system HOST may receive original video data corresponding to an original image from the outside. The host system HOST may divide the original video data by the number of display devices 10. For example, the host system HOST may divide the original video data into first video data corresponding to a first image, second video data corresponding to a second image, third video data corresponding to a third image, and fourth video data corresponding to a fourth image, in response to the first display device 11, the second display device 12, the third display device 13, and the fourth display device 14. The host system HOST may transmit the first video data to the first display device 11, transmit the second video data to the second display device 12, transmit the third video data to the third display device 13, and transmit the fourth video data to the fourth display device 14.

The first display device 11 may display the first image according to the first video data, the second display device 12 may display the second image according to the second video data, the third display device 13 may display the third image according to the third video data, and the fourth display device 14 may display the fourth image according to the fourth video data. Accordingly, the user may view the original image in which the first to fourth images displayed on the first to fourth display devices 11, 12, 13, and 14 are combined with each other.

Each of the plurality of display devices 11, 12, 13, and 14 constituting the tiled display TD may further include a broadcast tuner 410, a signal processor 420, a display 430, a speaker 440, a user interface 450, an HDD 460, a network communicator 470, a UI generator 480, and a controller 490. Components included in the plurality of display devices 11, 12, 13, and 14 are substantially the same as each other. Therefore, hereinafter, for convenience of explanation, components included in the first display device 11 will be mainly described below, and a repeated description of components included in the second display device 12, the third display device 13, and the fourth display device 14 will be omitted.

The broadcast tuner 410 may receive a broadcast signal of a corresponding channel through an antenna by tuning a channel frequency (e.g., predetermined channel frequency) under the control of the controller 490. The broadcast tuner 410 may include a channel detection module and a radio frequency (RF) demodulation module.

The broadcast signal demodulated by the broadcast tuner 410 is processed by the signal processor 420 and output to the display 430 and the speaker 440. Here, the signal processor 420 may include a demultiplexer 421, a video decoder 422, a video processor 423, an audio decoder 424, and an additional data processor 425.

The demultiplexer 421 demultiplexes the demodulated broadcast signal into a video signal, an audio signal, and additional data. The demultiplexed video signal, audio signal, and additional data may be reconstructed by the video decoder 422, the audio decoder 424, or the additional data processor 425, respectively. In this case, the video decoder 422, the audio decoder 424, and the additional data processor 425 may reconstruct the demultiplexed video signal, audio signal, and additional data to a decoding format corresponding to an encoding format at the time of transmitting the broadcast signal.

Meanwhile, a decoded video signal is converted by the video processor 423 so as to be suitable for a vertical frequency, resolution, an aspect ratio, and the like, conforming to an output standard of the display 430, and a decoded audio signal is output to the speaker 440.

The display 430 is a device displaying an image, and includes the pixels PX, the driver, and the like, described above.

The user interface 450 may receive a signal transmitted by the host system HOST. The user interface 450 may be provided so that the user may select commands related to communication with the other display devices 12 to 14 as well as data related to a selection of a channel and a selection and a manipulation of a user interface (UI) menu transmitted by the host system HOST and data for input may be input.

The HDD 460 stores various software programs including an operating system (OS) program, recorded broadcast programs, moving pictures, photographs, and other data, and may be formed as a storage medium, such as a hard disk or a non-volatile memory.

The network communicator 470 is provided to perform short-distance communication between the host system HOST and the other display devices 12 to 14, and may be implemented as a communication module including an antenna pattern capable of implementing mobile communication, data communication, Bluetooth™, RF, Ethernet, and the like.

The network communicator 470 may transmit and receive wireless signals to and from at least one of a base station, an external terminal, and a server on a mobile communication network constructed according to technical standards or communication methods for mobile communication (e.g., global system for mobile communication (GSM), code division multiple access (CDMA), CDMA2000™, enhanced voice-data optimized or enhanced voice-data Only (EV-DO), wideband CDMA (WCDMA), high speed downlink packet access (HSDPA), high speed uplink packet access (HSUPA), long term evolution (LTE), LTE-Advanced (LTE-A), 5G, etc.) through an antenna pattern to be described later.

The network communicator 470 may transmit and receive wireless signals on a communication network according to wireless Internet technologies through an antenna pattern to be described later. Examples of the wireless Internet technology include wireless local area network (WLAN), wireless-fidelity (Wi-Fi), Wi-Fi Direct, digital living network alliance (DLNA), wireless broadband (WiBro), world interoperability for microwave access (WiMAX), high speed downlink packet access (HSDPA), high speed uplink packet access (HSUPA), long term evolution (LTE), LTE-Advanced (LTE-A), and the like, and the antenna pattern transmits and receives data according to at least one wireless Internet technology within a range including Internet technologies that are not mentioned above.

The UI generator 480 generates a UI menu for communication between the host system HOST and the other display devices 12 to 14, and may be implemented by an algorithm code and an on screen display integrated chip (OSD IC). The UI menu for communication with the host system HOST and the other display devices 12 to 14 may be a menu for designating a counterpart digital television (TV) with which communication is desired and selecting a desired function.

The controller 490 is in charge of overall control of the first display device 11 and is in charge of communication control of the host system HOST and the second to fourth display devices 12 to 14, may store a corresponding algorithm code for control, and may be implemented by a microcontroller unit (MCU) in which the stored algorithm code is executed.

The controller 490 performs control to transmit a corresponding control command and data to the host system HOST and the second to fourth display devices 12 to 14 through the network communicator 470 according to an input and a selection of the user interface 450. When a control command (e.g., predetermined control command) and data are input from the host system HOST and the second to fourth display devices 12 to 14, the controller 490 performs an operation according to the control command.

Hereinafter, other embodiments of the display device 10 will be described. In the following embodiments, the same components as those of the above-described embodiments will be denoted by the same reference numerals, and an overlapping description thereof will be omitted or simplified, and contents different from those described above will be mainly described.

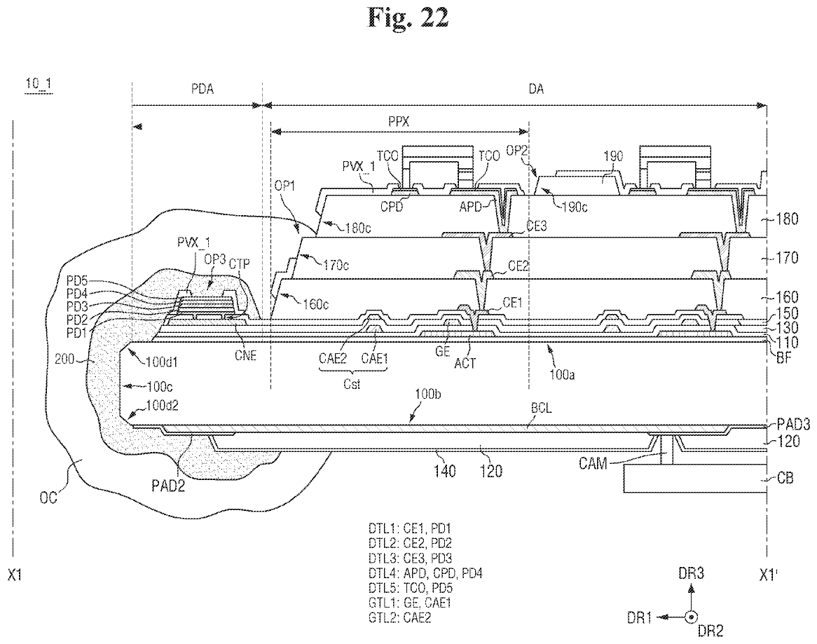

FIG. 22 is a schematic cross-sectional view illustrating a structure of a display device according to one or more other embodiments.

Referring to FIG. 22, it is illustrated that in a display device 10_1, an upper passivation layer PVX_1 may be partially located in the first exposure opening OP1. For example, the upper passivation layer PVX_1 may be partially located in the first exposure opening OP1 to cover at least portions of the first via sidewall 160c of the first via layer 160, an upper surface of the first via layer 160 exposed by the second via layer 170, the second via sidewall 170c of the second via layer 170, an upper surface of the second via layer 170 exposed by the third via layer 180, and/or the third via sidewall 180c of the third via layer 180.

This may be because the upper passivation layer PVX_1 remains partially unetched in an area corresponding to the first exposure opening OP1 in the manufacturing process of a display device described above.

The upper passivation layer PVX_1 covers at least portions of the first via sidewall 160c of the first via layer 160, the upper surface of the first via layer 160 exposed by the second via layer 170, the second via sidewall 170c of the second via layer 170, the upper surface of the second via layer 170 exposed by the third via layer 180, and/or the third via sidewall 180c of the third via layer 180 in the first exposure opening OP1, but still exposes a portion of the first via sidewall 160c, a portion of the second via sidewall 170c, and/or a portion of the third via sidewall 180c in the first exposure opening OP1, and thus, an exhaust gas GAS that may be generated in the manufacturing method of a display device may be discharged.

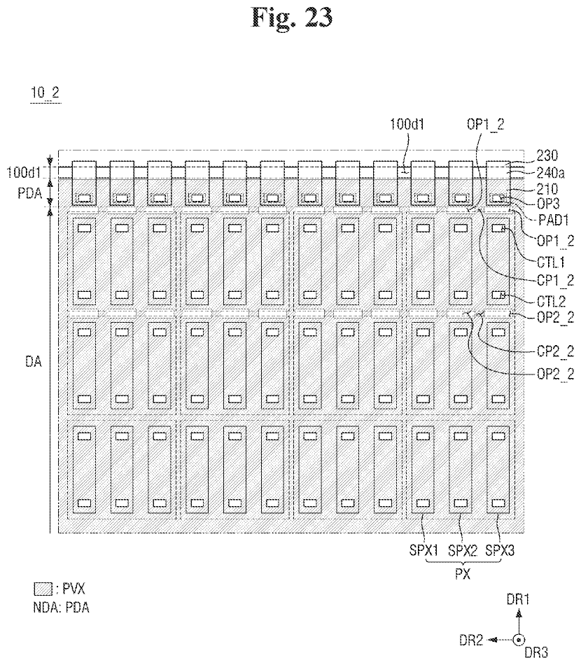

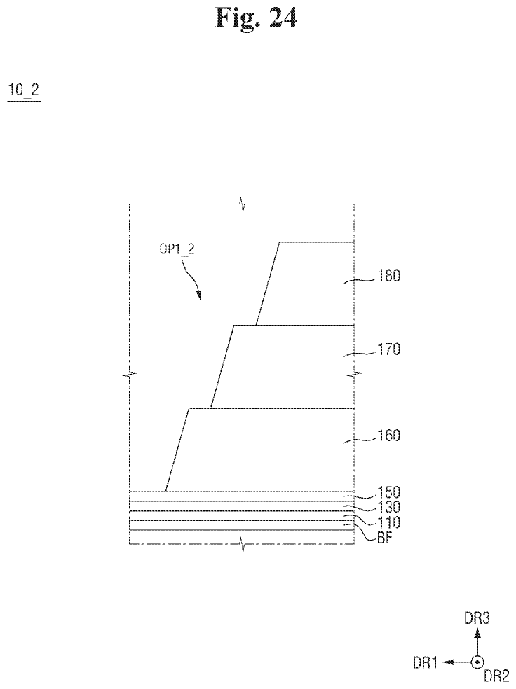

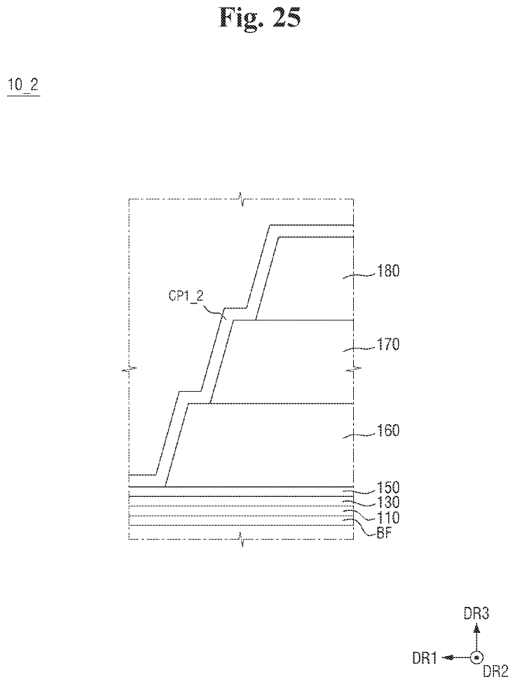

FIG. 23 is a plan view illustrating a profile of an upper passivation layer covering a front surface of a substrate of a display device according to still one or more other embodiments. FIG. 24 is a view illustrating a via layer exposed by an exposure opening according to still one or more other embodiments of FIG. 23. FIG. 25 is a view illustrating a via layer covered by a shielding pattern according to still one or more other embodiments of FIG. 23.

Referring to FIGS. 23 to 25, it is illustrated that in a display device 10_2, a plurality of first exposure openings OP1_2 and second exposure openings OP2_2 may be formed and may be spaced apart from each other. For example, the plurality of first exposure openings OP1_2 may be spaced from each other in the second direction DR2 and located side by side, and the plurality of second exposure openings OP2_2 may be spaced from each other in the second direction DR2 and located side by side.

In some embodiments, the plurality of first exposure openings OP1_2 may have substantially the same area and may be spaced apart from each other by a substantially constant interval, but are not limited thereto. For example, the plurality of first exposure openings OP1_2 may have different areas and may be spaced apart from each other by different intervals. Similarly, in some embodiments, the plurality of second exposure openings OP2_2 may have substantially the same area and may be spaced apart from each other by a constant interval, but are not limited thereto. For example, the plurality of second exposure openings OP2_2 may have different areas and may be spaced apart from each other by different intervals. It has been illustrated in FIG. 23 that the plurality of first exposure openings OP1_2 and the plurality of second exposure openings OP2_2 each have the same area and are spaced apart from each other by the same interval for convenience of explanation.

The plurality of first exposure openings OP1_2 may be spaced apart from each other with each of first shielding patterns CP1_2 interposed therebetween. The first shielding patterns CP1_2 may serve to define the plurality of first exposure openings OP1_2. Similarly, the plurality of second exposure openings OP2_2 may be spaced apart from each other with each of second shielding patterns CP2_2 interposed therebetween. The second shielding patterns CP2_2 may serve to define the plurality of second exposure openings OP2_2. Because the first exposure openings OP1_2 and the second exposure opening OP2_2 are formed by etching the upper passivation layer PVX as described above, the first shielding patterns CP1_2 may refer to portions located between the plurality of first exposure openings OP1_2 among unetched portions of the upper passivation layer PVX, and the second shielding patterns CP2_2 may refer to portions located between the plurality of second exposure openings OP2_2 among the unetched portions of the upper passivation layer PVX. Meanwhile, shapes of the first exposure opening OP1_2 and the first shielding pattern CP1_2 are substantially the same as shapes of the second exposure opening OP2_2 and the second shielding pattern CP2_2. Therefore, hereinafter, the first exposure opening OP1_2 and the first shielding pattern CP1_2 will be mainly described, and a detailed description of the second exposure opening OP2_2 and the second shielding pattern CP2_2 will be omitted.

The first exposure opening OP1_2 may expose the entirety of the first via sidewall 160c of the first via layer 160, an upper surface of the first via layer 160 exposed by the second via layer 170, the second via sidewall 170c of the second via layer 170, an upper surface of the second via layer 170 exposed by the third via layer 180, and the third via sidewall 180c of the third via layer 180, as illustrated in FIG. 24, but is not limited thereto. For example, as described with reference to FIG. 22, the first exposure opening OP1 may also expose only at least portions of the first via sidewall 160c of the first via layer 160, the upper surface of the first via layer 160 exposed by the second via layer 170, the second via sidewall 170c of the second via layer 170, the upper surface of the second via layer 170 exposed by the third via layer 180, and/or the third via sidewall 180c of the third via layer 180.

The first shielding pattern CP1_2 may cover the entirety of the first via sidewall 160c of the first via layer 160, the upper surface of the first via layer 160 exposed by the second via layer 170, the second via sidewall 170c of the second via layer 170, the upper surface of the second via layer 170 exposed by the third via layer 180, and the third via sidewall 180c of the third via layer 180, as illustrated in FIG. 25, but is not limited thereto. For example, the first shielding pattern CP1_2 may also cover only at least portions of the first via sidewall 160c of the first via layer 160, the upper surface of the first via layer 160 exposed by the second via layer 170, the second via sidewall 170c of the second via layer 170, the upper surface of the second via layer 170 exposed by the third via layer 180, and/or the third via sidewall 180c of the third via layer 180.

Through the configuration as described above, the first shielding pattern CP1_2 is interposed between a portion of the upper passivation layer PVX located in the pad area PDA and the other portion of the upper passivation layer PVX located in the display area DA to connect the one portion and the other portion of the upper passivation layer PVX to each other, and thus, it is possible to discharge the exhaust gas that may be generated in the manufacturing method of a display device while preserving structural stability of the upper passivation layer PVX.

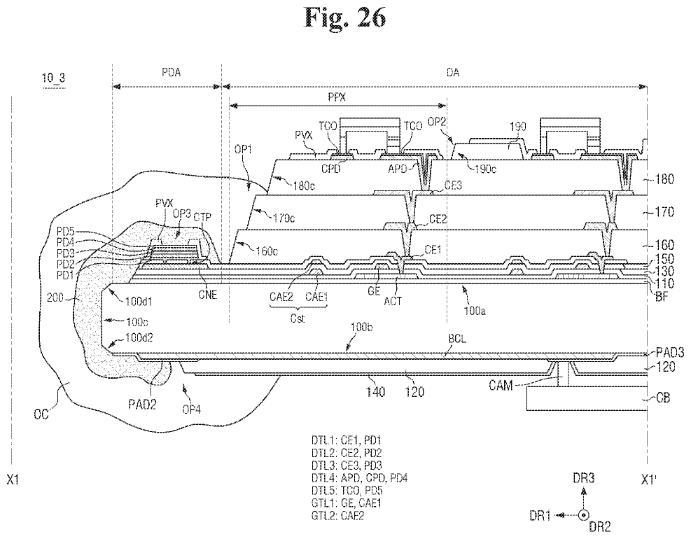

FIG. 26 is a schematic cross-sectional view illustrating a structure of a display device according to still one or more other embodiments.

Referring to FIG. 26, it is illustrated that in a display device 10_3, one side surface, in the first direction DR1, of the lower via layer 120 located on the second surface 100b of the substrate 100 may be exposed by the lower passivation layer 140. In other words, the lower passivation layer 140 may include a fourth exposure opening OP4 formed to expose a portion of the lower via layer 120 adjacent to the second pad PAD2.

The side wiring 200 may cover the second pad PAD2, but may not be in contact with one side surface, in the first direction DR1, of the lower via layer 120 exposed by the fourth exposure opening OP4. Accordingly, an exhaust gas GAS that may be generated in the upper via layer in a process of sintering the side wiring 200 may be discharged, and an exhaust gas GAS that may be generated in the lower via layer 120 in the process of sintering the side wiring 200 may be discharged through the fourth exposure opening OP4.

In concluding the detailed description, those skilled in the art will appreciate that many variations and modifications can be made to the embodiments without substantially departing from the aspects of the present disclosure. Therefore, the disclosed embodiments of the present disclosure are used in a generic and descriptive sense only and not for purposes of limitation.

What is claimed is:

1. A display device comprising:
a substrate comprising a first surface, a second surface opposite to the first surface, a first chamfered surface extending from one side of the first surface, a second chamfered surface extending from one side of the second surface, and a first side surface connecting the first chamfered surface and the second chamfered surface to each other;
a first pad on the first surface;
an upper via layer on the first surface and spaced from the first pad; and
a first passivation layer partially covering the upper via layer, and defining a first exposure opening exposing one side of the upper via layer facing the first pad.

2. The display device of claim 1, further comprising:
a second pad on the second surface; and
a side wiring on the first surface, on the first chamfered surface, on the first side surface, and on the second chamfered surface, and electrically connecting the first pad and the second pad to each other.

3. The display device of claim 2, further comprising an interlayer insulating layer between the first pad and the substrate, and between the upper via layer and the substrate,
wherein the side wiring is in direct contact with the interlayer insulating layer in an area between the first pad and the upper via layer.

4. The display device of claim 3, wherein the side wiring is spaced from the one side of the upper via layer facing the first pad.

5. The display device of claim 4, further comprising an overcoat layer covering the side wiring, and in direct contact with the one side of the upper via layer facing the first pad.

6. The display device of claim 5, further comprising a lower via layer on the second pad, and a second passivation layer partially covering the lower via layer,
wherein the second pad is closer to the second chamfered surface than the lower via layer, and
wherein the second passivation layer defines a second exposure opening exposing one side of the lower via layer adjacent to the second chamfered surface.

7. The display device of claim 6, wherein the side wiring is spaced from the one side of the lower via layer adjacent to the second chamfered surface.

8. The display device of claim 7, wherein the overcoat layer is in direct contact with the one side of the lower via layer adjacent to the second chamfered surface.

9. The display device of claim 1, wherein the upper via layer comprises a first via layer on the substrate, a second via layer on the first via layer, and a third via layer on the second via layer, and
wherein the display device further comprises:
a thin film transistor between the first via layer and the substrate; and
a light emitting element on the third via layer, and electrically connected to the thin film transistor.

10. The display device of claim 9, wherein the one side of the upper via layer facing the first pad and exposed by the first exposure opening comprises at least one of one side of the first via layer facing the first pad, one side of the second via layer facing the first pad, or one side of the third via layer facing the first pad.

11. The display device of claim 10, further comprising light emitting elements, which comprise the light emitting element, that are spaced from each other,
wherein the upper via layer further comprises fourth via layers between the light emitting elements, on the third via layer, and comprising an outermost fourth via layer adjacent to the first pad, and
wherein the first passivation layer defines a second exposure opening exposing one side of the outermost fourth via layer adjacent to the first pad.

12. The display device of claim 9, wherein the light emitting element is a flip chip-type micro light emitting diode element.

13. A display device comprising:
a substrate comprising a display area in which pixels are located, a pad area at one side of the display area, and an inclined area on one side of the pad area;
a passivation layer covering the display area and the pad area of the substrate;
a via layer between the substrate and the passivation layer in the display area; and
a pad between the substrate and the passivation layer in the pad area,
wherein the passivation layer defines:
a first exposure opening adjacent a boundary between the display area and the pad area in the display area, and exposing the via layer; and
a second exposure opening in the pad area and exposing the pad.

14. The display device of claim 13, further comprising a side wiring in the pad area and in the inclined area, and electrically connected to the pad through the second exposure opening.

15. The display device of claim 14, wherein the side wiring is spaced from the first exposure opening.

16. The display device of claim 15, further comprising side wirings, which comprise the side wiring, that are spaced from each other in a first direction, and wherein the first exposure opening extends in the first direction to correspond to the side wirings.

17. The display device of claim 16, wherein the pixels comprise an outermost pixel adjacent to the pad area,
wherein the passivation layer further defines a third exposure opening adjacent to the outermost pixel, and spaced from the first exposure opening with the outermost pixel interposed therebetween.

18. The display device of claim 15, further comprising side wirings, which comprise the side wiring, that are spaced from each other in a first direction,
wherein the passivation layer further defines first exposure openings, which comprise the first exposure opening, that are spaced from each other in the first direction.

19. A manufacturing method of a display device, the method comprising:
preparing a substrate comprising:
a first surface on which a first pad, a via layer spaced from the first pad, and an insulating layer covering the via layer are located;
a second surface on which a second pad is located and that opposes the first surface;
a first chamfered surface extending from one side of the first surface;
a second chamfered surface extending from one side of the second surface; and
a first side surface connecting the first chamfered surface and the second chamfered surface to each other;
forming an exposure opening in the insulating layer to expose one side of the via layer facing the first pad;
forming a side wiring material layer on the first surface, the second surface, the first chamfered surface, the second chamfered surface, and the first side surface of the substrate, and electrically connecting the first pad and the second pad to each other; and
forming a side wiring by irradiating the side wiring material layer with a laser,
wherein the first pad is closer to the first chamfered surface than the via layer.

20. The manufacturing method of a display device of claim 19, wherein the forming of the side wiring comprises discharging an exhaust gas generated by irradiating the via layer with the laser.

21. The manufacturing method of a display device of claim 20, wherein the exhaust gas is discharged through the exposure opening.

22. A tiled display device comprising:
display devices; and
seam parts between the display devices,
wherein a first display device of the display devices comprises:
a substrate comprising a first surface, a second surface opposite to the first surface, a first chamfered surface extending from one side of the first surface, a second chamfered surface extending from one side of the second surface, and a first side surface connecting the first chamfered surface and the second chamfered surface to each other;
an upper via layer on the first surface;
a first pad on the first surface and spaced from the upper via layer;
light emitting elements on the upper via layer; and
an first passivation layer covering the upper via layer, and defining a first exposure opening exposing one side of the upper via layer facing the first pad.

23. The tiled display device of claim 22, wherein the light emitting elements comprises a flip chip-type micro light emitting diode element.

24. The tiled display device of claim 22, wherein the substrate comprises glass.

25. The tiled display device of claim 22, wherein the first display device further comprises a side wiring on the first surface, on the second surface, and on the first side surface of the substrate, and connected to the first pad.

26. The tiled display device of claim 25, wherein the first display device further comprises:
a lower surface connection line on the second surface, and connected to the side wiring; and
a flexible film connected to the lower surface connection line through a conductive adhesive member.

27. The tiled display device of claim 22, wherein the display devices are arranged in a matrix form.
